(19) United States
(12) Patent Application Publication
(10) Pub. No.: US 2024/0188407 A1
(43) Pub. Date: Jun. 6, 2024

(54) METHODS FOR PURIFYING PEROVSKITE PRECURSORS AND IMPROVED PEROVSKITES MANUFACTURED THEREFROM

(71) Applicants: Alliance for Sustainable Energy, LLC, Golden, CO (US); First Solar, Inc., Tempe, AZ (US)

(72) Inventors: Axel Finn PALMSTROM, Golden, CO (US); Severin Niklas HABISREUTINGER, Oxford, Oxfordshire (GB); Joseph Jonathan BERRY, Boulder, CO (US); Zhibo ZHAO, Perrysburg, OH (US); Kelly Robert SCHUTT, Wheat Ridge, CO (US); Ross Allen KERNER, Wheat Ridge, CO (US)

(21) Appl. No.: 18/553,888

(22) PCT Filed: Apr. 6, 2022
(86) PCT No.: PCT/US22/71569

§ 371 Date: Oct. 4, 2023

Related U.S. Application Data
(60) Provisional application No. 63/171,228, filed on Apr. 6, 2021.

(51) Int. Cl. H10K 71/00; C07F 19/00; H10K 30/50; H10K 71/12; H10K 85/50

(52) U.S. Cl. CPC H10K 71/311; C07F 19/005; H10K 85/50; H10K 30/50; H10K 71/12

(57) ABSTRACT

The present disclosure relates to a method that includes preparing a mixture by dissolving at least two halide perovskite precursors in a first liquid, forming a halide perovskite crystal in the mixture by lowering a solubility limit of at least one of the halide perovskite precursors, and separating the halide perovskite crystal from the mixture, where at least one of the halide perovskite precursors contains an impurity, and the halide perovskite crystal is substantially free of the impurity.

### CROSS-REFERENCE TO RELATED APPLICATIONS

This application claims priority from U.S. Provisional Patent Application No. 63/171,228 filed on Apr. 6, 2021, the contents of which are incorporated herein by reference in their entirety.

### CONTRACTUAL ORIGIN

This invention was made under a Cooperative Research and Development Agreement, CRADA #CRD-13-507, between First Solar, Inc. and The National Renewable Energy Laboratory, operated for the United States Department of Energy. The United States Government has rights in this disclosure under Contract No. DE-AC36-08G028308 between the United States Department of Energy and Alliance for Sustainable Energy, LLC, the Manager and Operator of the National Renewable Energy Laboratory. The government has certain rights in this invention.

### BACKGROUND

The large-scale implementation of perovskite-containing devices such as solar cells, light-emitting diodes, and displays, requires the ability to produce such devices quickly and efficiently in a continuous fashion. Further, such full-scale manufacturing methods need to be flexible, robust, and capable of staying online, even when process conditions vary. This includes variations in the quality of the reactants used in the perovskite manufacturing process. Thus, there remains a need for improved methods for manufacturing perovskites that address these problems.

### SUMMARY

As aspect of the present disclosure is a method that includes preparing a mixture by dissolving at least two halide perovskite precursors in a first liquid, forming a halide perovskite crystal in the mixture by lowering a solubility limit of at least one of the halide perovskite precursors, and separating the halide perovskite crystal from the mixture, where at least one of the halide perovskite precursors contains an impurity, and the halide perovskite crystal is substantially free of the impurity. In some embodiments of the present disclosure, the halide perovskite crystal may include at least one of a 3D crystal, a 2D crystal, and/or a 1D crystal.

In some embodiments of the present disclosure, the halide perovskite crystal may have a chemical formula that includes at least one of ABX₃ or A₂BX₄, where A is a monovalent cation, B is a divalent metal cation, and X is a monovalent halide anion, and together, the at least two precursors provide A, B, and X. In some embodiments of the present disclosure, the perovskite crystal may have the formula Cs_{z}(FAₓMA₁₋ₓ)_{1-z},Pb(Cl_{w}(I_{y}Br_{1-y})_{1-w})₃, where 0≤w≤1, 0≤x≤1, 0≤y≤1, and 0≤z≤1. In some embodiments of the present disclosure, the halide perovskite crystal may include at least one of MAPbI₃, MAFACsPbIBr, FAPbI₃, FAPbBr₃, MAPbBr₃, CsPbBr₃, CsPbI₃, (CH₆N)PbI₃, and/or (C₄H₁₂N)₂PbBr₄.

In some embodiments of the present disclosure, the halide perovskite precursors may include BX₂ and AX. In some embodiments of the present disclosure, a BX₂ precursor may have a purity between about 95% and about 99.99% on a trace metals basis. In some embodiments of the present disclosure, the impurity may include a metal. In some embodiments of the present disclosure, the metal may include at least one of Na, Mg, Al, Si, K, Ca, Cr, Mn, Fe, Co, Ni, Cu, Zn, Ag, Ba, Bi, Rh, Pt, and/or Pd. In some embodiments of the present disclosure, the first liquid may include at least one of a polar solvent and/or an ionic liquid.

In some embodiments of the present disclosure, the forming further may include providing an additive to the mixture. In some embodiments of the present disclosure, the preparing may be performed with the mixture at a first temperature between about 20° C. and about 180° C. In some embodiments of the present disclosure, the forming may be performed with the mixture at a second temperature that is different than the first temperature. In some embodiments of the present disclosure, the forming may include at least one of evaporating at least a portion of the mixture, applying ultrasound to the mixture, applying a mechanical treatment to the mixture, an acoustical treatment of the mixture, a pressure treatment of the mixture, an electrical treatment of the mixture, and/or an electromagnetic treatment of the mixture.

In some embodiments of the present disclosure, after the forming, the mixture may include the halide perovskite crystal, as a solid phase, and a liquid phase comprising the impurity. In some embodiments of the present disclosure, the separating may result in the separation of the mixture into the halide perovskite crystal as a solid stream and an effluent stream, where the effluent stream includes the liquid phase and the impurity. In some embodiments of the present disclosure, the method may further include, after the separating, a removing from the halide perovskite crystal any remaining portion of the impurity. In some embodiments of the present disclosure, the method may further include, after the separating, forming a halide perovskite film, where the forming utilizes the halide perovskite crystal as a precursor, and the perovskite film has substantially the same composition of A, B, and X as the halide perovskite crystal precursor.

An aspect of the present disclosure is a composition that includes a halide perovskite having a composition of at least one of ABX₃ or A₂BX₄, where A is a monovalent cation, B is a divalent metal cation, and X is a monovalent halide anion, and the halide perovskite further includes N-methylformamidinium. In some embodiments of the present disclosure, the film may further include methylammonium at a concentration between 0 wt % and 1 wt %.

### BRIEF DESCRIPTION OF THE DRAWINGS

Some embodiments are illustrated in referenced figures of the drawings. It is intended that the embodiments and figures disclosed herein are to be considered illustrative rather than limiting.

FIGS. 1A, 1B, and 1C illustrate a perovskite, according to some embodiments of the present disclosure.

FIG. 2 illustrates 2D, 1D, and OD perovskite structures, in Panels A, B, and C, respectively, according to some embodiments of the present disclosure.

FIG. 3 illustrates a method for producing a halide perovskite crystal, according to some embodiments of the present disclosure.

FIG. 4 illustrates examples of purified halide perovskite crystal precursors, synthesized by the methods described herein, according to some embodiments of the present disclosure.

FIG. 5 illustrates seed crystals (i.e., purified halide perovskite crystals) forming in a starting mixture (left) and a point later in time after substantial precipitation of dissolved species has occurred (right), according to some embodiments of the present disclosure.

FIG. 6 illustrates XRD characterization of a halide perovskite crystal (Cs_{0.05}FA_{0.87}MA_{0.08}PbI_{2.76}Br_{0.24}) synthesized using the methods described herein, according to some embodiments of the present disclosure.

FIG. 7 illustrates UV-Vis absorbance spectra of a control film of perovskite material formed by a “traditional” (control) method and using the novel methods described herein (labeled “bulk-crystal”), both of nominal composition: Cs_{0.05}FA_{0.87}MA_{0.08}PbI_{2.76}Br_{0.24}, according to some embodiments of the present disclosure.

FIGS. 8A-8D illustrate a comparison of device performance metrics for devices using perovskite films (Cs_{0.05}FA_{0.87}MA_{0.08}PbI_{2.76}Br_{0.24}) fabricated using a traditional method (FIGS. 8A and 8B) of inks utilizing a mixture of precursor salts to the method described herein using a single perovskite precursor containing all of the individual elements (FIGS. 8C and 8D), according to some embodiments of the present disclosure.

FIGS. 9A-9D illustrate stability data of devices (ITO/PTAA/Perovskite/C₆₀/BCP/Ag) constructed with perovskite films fabricated using either a “traditional” mixed salt approach or the single precursor method described herein, according to some embodiments of the present disclosure.

FIGS. 10A and 10B illustrate device performance made by the methods described herein, according to some embodiments of the present disclosure.

FIG. 10C illustrates J-V scans of best-performing devices made by the methods described herein, according to some embodiments of the present disclosure.

FIGS. 11A-11D illustrate the performance metrics of devices made using different perovskite precursors/starting materials, according to some embodiments of the present disclosure. (L=low purity salt perovskite precursors; SL=purified single crystal perovskite precursors generated low purity salt perovskite precursors by the methods described herein; H=high purity salt perovskite precursors; and HL=purified single crystal perovskite precursors generated high purity salt perovskite precursors by the methods described herein.) FIGS. 12A-12D illustrate stability data of devices made using different perovskite precursors/starting materials, according to some embodiments of the present disclosure.

FIG. 13A illustrates XRD results of perovskites made by the methods described herein, according to some embodiments of the present disclosure.

FIG. 13B illustrates PL emission data from perovskites made by the methods described herein, according to some embodiments of the present disclosure.

FIGS. 14A and 14B illustrate ToF-SIMS results of impurities of starting of starting perovskite precursors versus treated perovskite precursors, according to some embodiments of the present disclosure.

FIGS. 15A and 15B illustrate NMR data of impurities in the as-received precursor salts and their successful removal from the final treated perovskite crystals by the methods described herein, according to some embodiments of the present disclosure.

FIG. 16 illustrates NMR data that verify solvent impurities can result in undesired side reactions.

FIG. 17 illustrates an exemplary device stack that was fabricated using perovskite precursors synthesized using the methods described herein, according to some embodiments of the present disclosure.

FIGS. 18A and 18B illustrate perovskite crystals made by the methods described herein, according to some embodiments of the present disclosure.

### REFERENCE NUMBERS

100 . . . . . . . . . . . . . . . . . . . . . . . . . . . perovskite
110 . . . . . . . . . . . . . . . . . . . . . . . . . . . A-cation
120 . . . . . . . . . . . . . . . . . . . . . . . . . . . B-cation
130 . . . . . . . . . . . . . . . . . . . . . . . . . . . X-anion
300 . . . . . . . . . . . . . . . . . . . . . . . . . . . method
302 . . . . . . . . . . . . . . . . . . . . . . . . . . . halide perovskite precursor
304 . . . . . . . . . . . . . . . . . . . . . . . . . . . first liquid
310 . . . . . . . . . . . . . . . . . . . . . . . . . . . preparing
312 . . . . . . . . . . . . . . . . . . . . . . . . . . . starting mixture
314 . . . . . . . . . . . . . . . . . . . . . . . . . . . additive
320 . . . . . . . . . . . . . . . . . . . . . . . . . . . forming
322 . . . . . . . . . . . . . . . . . . . . . . . . . . . intermediate mixture
330 . . . . . . . . . . . . . . . . . . . . . . . . . . . separating
332 . . . . . . . . . . . . . . . . . . . . . . . . . . . first effluent stream
334 . . . . . . . . . . . . . . . . . . . . . . . . . . . first halide perovskite (i.e., precipitated crystals)
336 . . . . . . . . . . . . . . . . . . . . . . . . . . . wash liquid
340 . . . . . . . . . . . . . . . . . . . . . . . . . . . removing
342 . . . . . . . . . . . . . . . . . . . . . . . . . . . second halide perovskite (i.e., washed crystals)
350 . . . . . . . . . . . . . . . . . . . . . . . . . . . drying
352 . . . . . . . . . . . . . . . . . . . . . . . . . . . second effluent stream
354 . . . . . . . . . . . . . . . . . . . . . . . . . . . halide perovskite (i.e., final purified crystals)

### DETAILED DESCRIPTION

The present disclosure may address one or more of the problems and deficiencies of the prior art discussed above. However, it is contemplated that some embodiments as disclosed herein may prove useful in addressing other problems and deficiencies in a number of technical areas.

Therefore, the embodiments described herein should not necessarily be construed as limited to addressing any of the particular problems or deficiencies discussed herein.

References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, 5%, or ±1% of a specific numeric value or target.

In some embodiments of the present invention, the term “about” is used to indicate an uncertainty limit of less than or equal to ±1%, 0.9%, ±0.8%, ±0.7%, 0.6%, ±0.5%, 0.4%, ±0.3%, 0.2%, or ±0.1% of a specific numeric value or target.

The present disclosure relates to, among other things, methods for purifying relatively low-quality halide perovskite precursor salts by solubilizing the salts and then crystallizing the precursors into bulk halide perovskite crystals (single crystal or polycrystalline) and/or halodoplumbate polymorphs related to perovskites and sharing the same stoichiometry, but do not adopt the perovskite crystal structure (e.g., orthorhombic CsPbI₃). In some embodiments of the present disclosure, the resultant bulk halide perovskite crystals (e.g., ABX₃) may be mixed (e.g., ball-milled) and dissolved into solvents to form a solution which can be subsequently used to create high-quality halide perovskite thin films. This approach can be applied to perovskite formulations having mixed A-site cations and/or mixed X-site anions, as well as other formulations. As demonstrated herein, solar cells incorporating perovskite films synthesized in this fashion demonstrated substantially improved power conversion efficiencies (PCEs) when compared to devices manufactured using the same low-quality salts, such as PbI₂, but without the purification process. Furthermore, it is demonstrated herein that fast crystallization techniques to produce bulk, polycrystalline ABX₃ crystals may obtain the benefits of the precursor ABX₃ treatment methods described herein, enabling these methods to be implemented in the short time-scales desirable for large scale manufacturing processes.

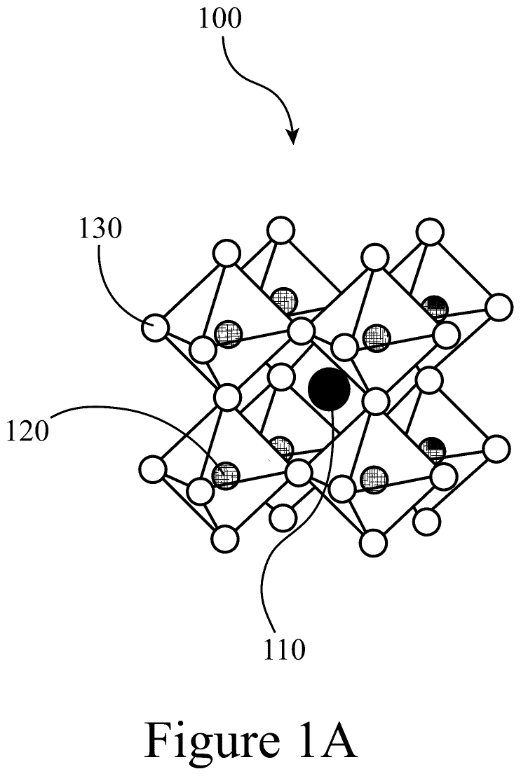

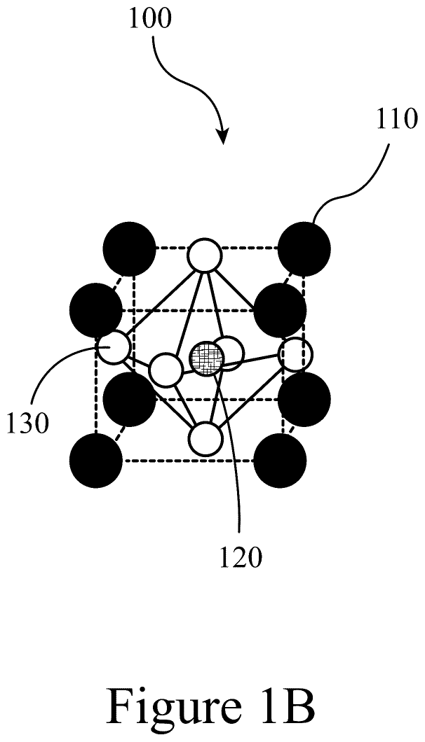

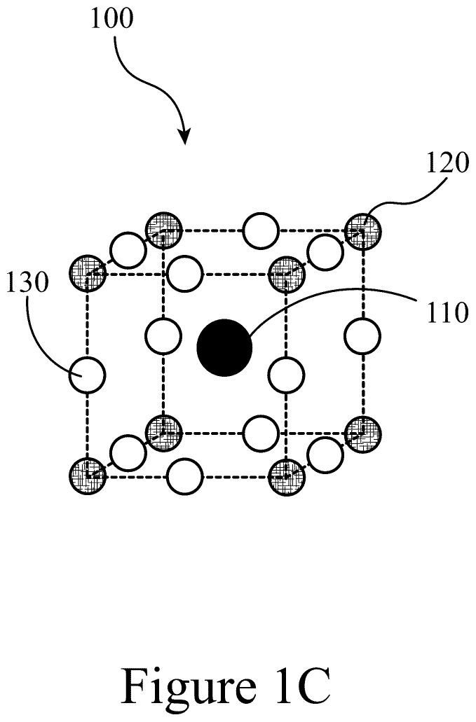

FIGS. 1A, 1B, and 1C illustrate that perovskites 100, for example halide perovskites, may organize into pseudo-cubic crystalline structures with corner-sharing octahedra, as well as other crystalline structures such as tetragonal, hexagonal, and orthorhombic with either edge-or face-sharing octahedra, and may be described by the general formula ABX₃, where X (130) is an anion and A (110) and B (120) are cations, typically of different sizes. In some embodiments of the present disclosure, a perovskite may have a layered structure that includes 3D structures described above positioned between sheets of organic cations; these are often termed 2D perovskites. Mixture of the 2D and 3D phases are also possible. FIG. 1A illustrates that a perovskite 100 may be organized into eight octahedra surrounding a central A-cation 110, where each octahedra is formed by six X-anions 130 surrounding a central B-cation 120.

FIG. 1B illustrates that a perovskite 100 may be visualized as a cubic unit cell, where the B-cation 120 is positioned at the center of the cube, an A-cation 110 is positioned at each corner of the cube, and an X-anion 130 is face-centered on each face of the cube. FIG. 1C illustrates that a perovskite 100 may also be visualized as a cubic unit cell, where the B-cation 120 resides at the eight corners of a cube, while the A-cation 110 is located at the center of the cube and with 12 X-anions 130 centrally located between B-cations 120 along each edge of the unit cell.

For both unit cells illustrated in FIGS. 1B and 1C, the A-cations 110, the B-cations 120, and the X-anions 130 balance to the general formula ABX₃, after accounting for the fractions of each atom shared with neighboring unit cells. For example, referring to FIG. 1B, the single B-cation 120 atom is not shared with any of the neighboring unit cells. However, each of the six X-anions 130 is shared between two unit cells, and each of the eight A-cations 110 is shared between eight unit cells. So, for the unit cell shown in FIG. 1B, the stoichiometry simplifies to B=1, A=8*0.125=1, and X=6*0.5=3, or ABX₃. Similarly, referring again to FIG. 1C, since the A-cation is centrally positioned, it is not shared with any of the unit cells neighbors. However, each of the 12 X-anions 130 is shared between four neighboring unit cells, and each of the eight B-cations 120 is shared between eight neighboring unit cells, resulting in A=1, B =8 *0.125=1, and X=12*0.25=3, or ABX₃. Referring again to FIG. 1C, the X-anions 130 and the B-cations 120 are shown as aligned along an axis; e.g. where the angle at the X-anion 130 between two neighboring B-cations 120 is exactly 180 degrees, referred to herein as the tilt angle. However, a perovskite 100 may have a tilt angle not equal to 180 degrees. For example, some embodiments of the present disclosure may have a tilt angle between 153 and 180 degrees.

Typical inorganic perovskites include calcium titanium oxide (calcium titanate) minerals such as, for example, CaTiO₃ and SrTiO₃. In some embodiments of the present invention, the A-cation 110 may include a nitrogen-containing organic compound such as an alkyl ammonium compound. The B-cation 120 may include a metal and the X-anion 130 may include a halogen. Additional examples for the A-cation 110 include organic cations and/or inorganic cations, for example Cs, Rb, K, Na, Li, and/or Fr. Organic A-cations 110 may be an alkyl ammonium cation, for example a C₁₋₂₀ alkyl ammonium cation, a C₁₋₆ alkyl ammonium cation, a C₂₋₆ alkyl ammonium cation, a C₁₋₅ alkyl ammonium cation, a C₁₋₄ alkyl ammonium cation, a C₁₋₃ alkyl ammonium cation, a C₁₋₂ alkyl ammonium cation, and/or a C₁ alkyl ammonium cation. Further examples of organic A-cations 110 include methylammonium (CH₃NH₃+), ethylammonium (CH₃CH₂NH₃+), propylammonium (CH₃CH₂ CH₂NH₃+), butylammonium (CH₃CH₂ CH₂ CH₂NH₃+), formamidinium (NH₂CH═NH₂+), hydrazinium, acetylammonium, dimethylammonium, imidazolium, guanidinium, benzylammonium, phenethylammonium, butylammonium and/or any other suitable nitrogen-containing or organic compound. In other examples, an A-cation 110 may include an alkylamine. Thus, an A-cation 110 may include an organic component with one or more amine groups. For example, an A-cation 110 may be formamidinium (CH(NH₂)₂). Thus, the A-cation 110 may include an organic constituent in combination with a nitrogen constituent. In some cases, the organic constituent may be an alkyl group such as straight-chain or branched saturated hydrocarbon group having from 1 to 20 carbon atoms. In some embodiments, an alkyl group may have from 1 to 6 carbon atoms. Examples of alkyl groups include methyl (C₁), ethyl (C₂), n-propyl (C₃), isopropyl (C₃), n-butyl (C₄), tert-butyl (C₄), sec-butyl (C₄), iso-butyl (C₄), n-pentyl (Cs), 3-pentanyl (Cs), amyl (Cs), neopentyl (Cs), 3-methyl-2-butanyl (Cs), tertiary amyl (Cs), and n-hexyl (C₆). Additional examples of alkyl groups include n-heptyl (C₇), n-octyl (Cs) and the like. Examples of metal B-cations 120 include, for example, lead, tin, germanium, and or any other 2+ valence state metal that can charge-balance the perovskite 100. Further examples include transition metals in the 2+ state such as Mn, Mg, Zn, Cd, and/or lanthanides such as Eu. B-cations may also include elements in the 3+ valence state, as described below, including for example, Bi, La, and/or Y. Examples for X-anions 130 include halogens: e.g. fluorine, chlorine, bromine, iodine and/or astatine. In some cases, the perovskite halide may include more than one X-anion 130, for example pairs of halogens; chlorine and iodine, bromine and iodine, and/or any other suitable pairing of halogens. In other cases, the perovskite 100 may include two or more halogens of fluorine, chlorine, bromine, iodine, and/or astatine.

Thus, the A-cation 110, the B-cation 120, and X-anion 130 may be selected within the general formula of ABX₃ to produce a wide variety of perovskites 100, including, for example, methylammonium lead triiodide (CH₃NH₃PbI₃), and mixed halide perovskites such as CH₃NH₃PbI₃₋ₓClₓ and CH₃NH₃PbI₃₋ₓBrₓ. Thus, a perovskite 100 may have more than one halogen element, where the various halogen elements are present in non-integer quantities; e.g., x is not equal to 1, 2, or 3. In addition, perovskite halides, like other organic-inorganic perovskites, can form three-dimensional (3-D), two-dimensional (2-D), one-dimensional (1-D) or zero-dimensional (0-D) networks, possessing the same unit structure. As described herein, the A-cation 110 of a perovskite 100, may include one or more A-cations, for example, one or more of cesium, FA, MA, etc. Similarly, the B-cation 120 of a perovskite 100, may include one or more B-cations, for example, one or more of lead, tin, germanium, etc. Similarly, the X-anion 130 of a perovskite 100 may include one or more anions, for example, one or more halogens (e.g., at least one of I, Br, Cl, and/or F), thiocyanate, and/or sulfur. Any combination is possible provided that the charges balance.

For example, a perovskite having the basic crystal structure illustrated in FIGS. 1A-1C, in at least one of a cubic, orthorhombic, and/or tetragonal structure, may have other compositions resulting from the combination of the cations having various valence states in addition to the 2+ state and/or 1+ state described above for lead and alkyl ammonium cations; e.g. compositions other than AB²⁺X₃ (where A is one or more cations, or for a mixed perovskite where A is two or more cations). Thus, the methods described herein may be utilized to create novel mixed cation materials having the composition of a double perovskite (elpasolites), A₂B¹⁺B³⁺X₆, with an example of such a composition being Cs₂BiAgCl₆ and Cs₂CuBiI₆.

Another example of a composition covered within the scope of the present disclosure is described by A₂B⁴⁺X₆, for example Cs₂PbI₆ and Cs₂SnI₆. Yet another example is described by A₃B₂³⁺X₉, for example Cs₃Sb₂I₉. For each of these examples, A is one or more cations, or for a mixed perovskite, A is two or more cations.

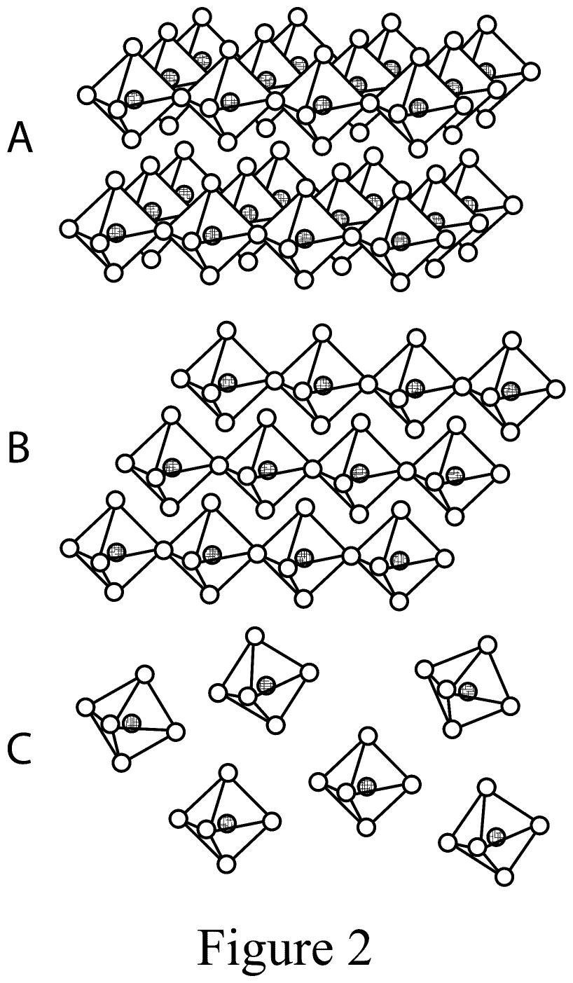

In addition, perovskite halides, like other organic-inorganic perovskites, can form a three-dimensional (3D) network, a two-dimensional (2D) network, a one-dimensional (1D) network and/or a zero-dimensional (OD) network, possessing the same unit formula. A perovskite's 3D network is illustrated in FIGS. 1A, 1i, and 1C. FIG. 2 illustrates a 2D perovskite network, a 1D coordination polymer network, and a OD arrangement, in Panels A, B, and C, respectively. As described above, a 3D perovskite may adopt a general chemical formula of ABX₃, in which the A-cation may be a monovalent cation (e.g., methylammonium and/or formamidinium CH(NH₂)₂⁺), the B-cation may be a divalent cation (e.g., Pb²⁺ and/or Sn²⁺), and the X-anion may be a halide anion (I⁻, Br⁻, and/or Cl⁻). In this formula, the 3D network of perovskites may be constructed by linking all corner sharing BX₆ octahedra, with the A-cation filling the space between eight octahedral unit cells to balance the crystal charge.

Referring to Panel A of FIG. 2, through the chemically accomplished dimensional reduction of the 3D crystal lattice, 2D perovskites, (A′)ₘ(A)ₙ₋₁BₙX₃ₙ₊₁, may adopt a new structural and compositional dimension, A′ (not shown), where monovalent (m=2) or divalent (m=1) cations can intercalate between the X-anions of the 2D perovskite sheets. Referring to Panel B of FIG. 2, 1D perovskites are constructed by BX₆ octahedral chained segments spatially isolated from each other by surrounding bulky organic cations (not shown), leading to bulk assemblies of paralleled octahedral chains. Referring to Panel C of FIG. 2, typically, the OD perovskites are constructed of isolated inorganic octahedral clusters and surrounded by small cations (not shown) which are connected via hydrogen bonding.

The present disclosure relates to methods for making perovskites, as described above. Such methods may, among other things, enable the use of less pure (and less costly) perovskite precursors at high speeds and manufacturing scale, resulting in the synthesis of high-quality perovskite films for use in various devices including solar cells, displays, light-emitting diodes, etc. As described herein, exemplary methods include treating relatively impure halide perovskite precursors, resulting in the forming of relatively pure halide perovskite crystals, which may be subsequently used as precursors to make high quality crystalline halide perovskite films to be utilized in the targeted devices. For example, the purified perovskite crystals obtained from relatively impure perovskite precursors may be subsequently dissolved in a solvent and applied via a solution processing method to a substrate. The liquid film may then be treated (e.g., heated, exposed to a gas flow) thereby converting the liquid film to a solid perovskite layer. Further, the methods described herein may impact the recycle and/or reuse of the raw materials used to manufacture perovskite-containing materials and devices.

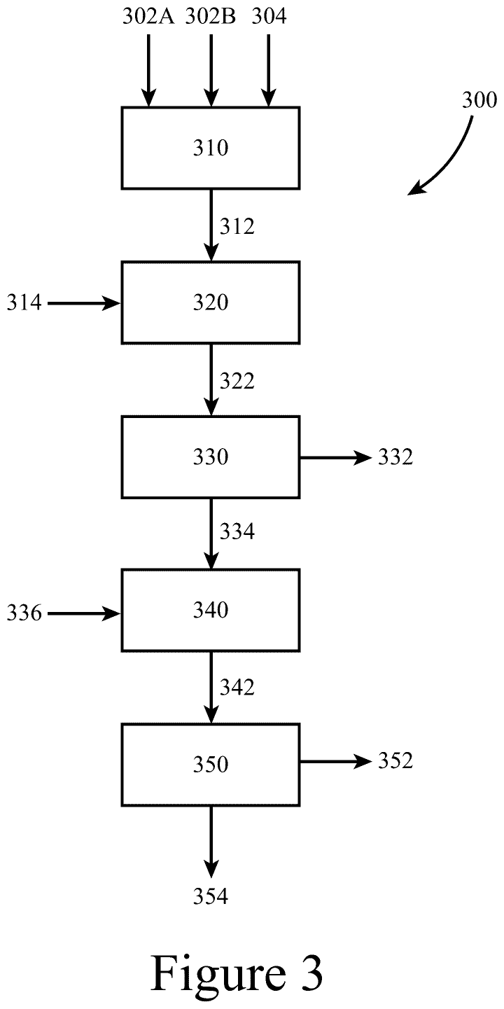

FIG. 3 illustrates an exemplary method 300 for producing a purified halide perovskite 354 to be subsequently used as improved and/or purified halide perovskite precursors in downstream manufacturing steps to produce a variety of perovskite-containing devices (e.g., solar cells, LEDs, displays, sensors, etc.), according to some embodiments of the present disclosure. The method 300 may include a number of steps in series, including preparing 310 a starting mixture 312 by dissolving at least two halide perovskite precursors (302A and 302B), e.g., PbI₂ and methylammonium iodide (MAI), where at least one of the halide perovskite precursors is relatively impure, in a first liquid 304 (i.e., solvent). Once dissolved, the method 300 may proceed with the forming 320 of a relatively pure solid halide perovskite precursor by precipitating it from the starting mixture 312. As described herein, this may be achieved by lowering the solubility limit of at least one of the two starting halide perovskite precursors (302A and/or 302B) in the starting mixture 312, resulting in the forming 320 of the purified halide perovskite precursor contained within an intermediate mixture 322. Other forming steps 320 may utilize the addition of a seed crystal to initiate precipitation of the now purified perovskite solid. Thus, in some embodiments of the present disclosure, a purified halide perovskite may have the stoichiometry ABX₃, and/or any other perovskite as defined above. In some embodiments of the present disclosure, a method like that illustrated in FIG. 3 may be used to purify the starting salts, such as PbI₂, without forming a perovskite crystal. Other salts that may be similarly purified are AX salts and/or BX₂ salts (of which PbI₂ is one example).

This forming 320 (i.e., precipitating) of the purified halide perovskite precursor may be accomplished by a variety of methods including changing the temperature of the starting mixture 312, evaporating at least a portion of the starting mixture 312, introducing an additive 314 to the starting mixture 312, and/or by the introduction of at least one of a mechanical input, an acoustic input, the introduction of and/or infiltration of a non-solvent, and/or an electromagnetic input. Note that although FIG. 3 illustrates the steps of the method occurring in series, this is for illustrative purposes and in some embodiments of the present disclosure, one or more steps may be combined into a single step. For example, in some embodiments of the present disclosure, the preparing 310 and the forming 320 may be performed in parallel; e.g., at substantially the same point in time.

As described above, the final targeted, purified halide perovskite 354 may be any desired halide perovskite having at least one of a 3D, 2D, and/or 1D crystalline form. Examples of a relatively pure halide perovskite 354 includes those having a chemical formula of at least one of ABX₃ and/or A₂BX₄, where A includes a monovalent cation, B includes a divalent metal cation, and X includes a monovalent halide anion. Examples of desirable targeted halide perovskites 354 include at least one (CH₆N)PbI₃ (MAPbI₃), MAPbBr₃, (C₄H₁₂N)₂PbBr₄, CH(NH₂)₂PbI₃ FAPbI₃, FAPbBr₃, CsPbBr₃, CsPbI₃, Cs_{z}(FAₓMA₁₋ₓ)_{1-z}Pb(I_{y}Br_{1-y})₃. (e.g., MA_{0.08}FA_{0.87}Cs_{0.05}PbI_{2.76}Br_{0.24}), Cs_{z}(FAₓMA₁₋ₓ)_{1-z}Pb(Cl_{w}(I_{y}Br_{1-y})_{1-w})₃, and/or the Sn, Bi, and/or Sb analogs of these exemplary perovskites, etc. To obtain the targeted halide perovskite 354, the starting (relatively impure) halide perovskite precursors (302A and 302B) should provide the necessary components A, B, and X. Thus, in some embodiments of the present disclosure, the starting halide perovskite precursors (302A and 302B) may include two or more salts that together provide A, B, and X, for example salts having the chemical formulas of BX₂ and AX. In some embodiments of the present disclosure, a starting halide perovskite precursor (302A and/or 302B) of BX₂ may have a purity between about 95% and about 99.99% on a trace metals basis (per vendor standard methods), where examples of trace metals include at least one of Na, Mg, Al, Si, K, Ca, Cr, Mn, Fe, Co, Ni, Cu, Zn, Ag, Ba, Bi, Rh, Pt, and/or Pd. In some embodiments of the present disclosure, a starting halide perovskite precursor (302A and/or 302B) of BX₂ may have X and B present at a ratio of X:B between about 1:1 and about 1.99:1. In some embodiments of the present disclosure, a starting halide perovskite precursor (302A and/or 302B) of AX may have a purity between about 95% and about 99.9% on a trace metals basis, with examples of trace metal provided above.

Examples of A, B, and X are provided above. More specifically, in some embodiments of the present disclosure, A (i.e., A-cation) may include at least one of an alkali metal, an alkylammonium, a phenylalkylammonium, an arylammonium, and/or an allylammonium. Examples of an alkali metal includes at least one cesium, rubidium, and/or potassium. Examples of an alkylammonium include at least one of methylammonium (MA), formamidinium (FA), butylammonium (BA), dimethylammonium (DA), and/or guanidinium. Examples of a phenylalkylammonium include at least one of phenethylammonium (PEA), 4-fluoro-phenethylammonium iodide, pentafluoro-phenethylammonium, and/or any molecule containing at least one aromatic phenyl group and an alkyl group. As described herein, B may include at least one of lead or tin. X may include a halide such as at least one of iodide, bromide, chloride, and/or fluoride.

In some embodiments of the present disclosure, the forming 310 of a starting mixture 312 may be achieved using a first liquid 304 that includes at least one of a polar solvent and/or an ionic liquid. A polar solvent may be a protic solvent and/or an aprotic solvent. Examples of protic polar solvents include at least one of water, methanol, and/or isopropanol. Examples of aprotic polar solvents include at least one of acetonitrile, dimethylformamide, dimethylsulfoxide, methyl-2-pyrrolidone, and/or γ-butyrolactone. Examples of ionic liquids include at least one of 1-butyl-3-methylimidazolium tetrafluoroborate (BMIM:BF4), 3-methylimidazolium hexafluorophosphate (BMIM:PF6), imidazolium tetrafluoroborate (IM:BF4), 1-butyl-1-methylpiperidinium tetrafluoroborate (BMP:BF4), and/or 1-butyl-1-methylpiperidinium hexafluorophosphate (BMP:PF6). As described below, the specifics of a subsequent forming 320 (i.e., precipitating) of a purified target halide perovskite precursor (eventually 354) may depend upon the composition of the starting mixture 312; e.g., the specific starting halide perovskite precursors (302A and/or 302B) and the first liquid 304. In some embodiments of the present disclosure, a first liquid 304 may be a mixture of different liquids.

In some embodiments of the present disclosure, the forming 320 (i.e., precipitation) of a purified halide perovskite precursor may be achieved by changing the temperature of the starting mixture 312, such that the temperature change lowers the solubility of at least one of the starting halide perovskite precursors (302A and/or 302B). Thus, in some embodiments of the present disclosure, the preparing 310 of the starting mixture 312 may be performed at a first temperature, whereas the forming 320 of the relatively pure halide perovskite (eventually 354) may be performed at a second temperature that is different than the first temperature. For example, the first temperature may be higher than the second temperature or the first temperature may be lower than the second temperature. In some embodiments of the present disclosure, a first temperature of a starting mixture 312 may be between about 20° C. and about 180° C. and a second temperature of the mixture during a forming step 320 may be between about 20° C. and about 180° C. In some embodiments of the present disclosure, the second temperature of the mixture during a forming step 320 may not be constant.

However, changing the temperature of a starting mixture 312 is described for illustrative purposes and is just one example of how to affect the solubility of the perovskite precursors contained in a starting mixture 312. In some embodiments of the present disclosure, the solubility of at least one of the starting halide perovskite precursors (302A and/or 302B) may be achieved with the operating temperatures during the preparing 310 and forming 320 being substantially equal. Referring again to FIG. 3, in some embodiments of the present disclosure, the forming 320 (i.e., precipitating) of the targeted, purified halide perovskite precursor (starting with the solid produced in the forming 320 step and contained in the intermediate mixture 322 and eventually 354) may be achieved by the introduction of an additive 314 to the mixture 312. Examples of additives 314 include at least one of a liquid, a solid, and/or a gas.

Examples of liquid additives 314 that may induce the forming 320 of the purified halide perovskite include at least one of an oil, an acid, an ionic liquid, an antisolvent, and/or water.

An acid additive 314 may include at least one of an organic acid and/or an inorganic acid with examples including formic acid and/or acetic acid and/or a hydrohalic (e.g., HCl, HI, HBr, and/or HF), a hypophosphorous acid (HPA), respectively. An oil additive 314 may include at least one of a silicone oil and/or a petroleum-based oil. An ionic liquid additive 314 may include at least one of BMIM:BF4 (1-Butyl-3-methylimidazolium tetrafluoroborate) and/or BMIM:PF6 (1-Butyl-3-methylimidazolium hexafluorophosphate). An antisolvent additive 314 may include at least one of chlorobenzene, diethyl ether, methyl acetate, or toluene. An example of a solid additive is a perovskite crystal or alternative lattice-matched material, such as lead sulfide. This process additionally embodies stabilizers and additives that scavenge impurities present in the starting salts or formed in situ such as an aldehyde to scavenge undesired methylamine formed under atmospheric conditions. In some embodiments of the present disclosure, the forming 320 of a higher purity halide perovskite precursor (eventually 354) from at least one of the lower purity halide perovskite precursors (302A and/or 302B) may be achieved by evaporating at least a portion of the mixture 320 and/or by applying one or more mechanical (e.g., ball milling), acoustical, pressure, electrical, and/or electromagnetic treatments (e.g., applying microwaves) to the mixture 312. For example, an acoustical treatment for aiding in the forming 320 step may include the applying of ultrasound to the mixture 312.

Referring again to FIG. 3, once the purified halide perovskite (eventually 354) has been precipitated in the forming 320 step, as a solid phase suspended in the liquid phase of the intermediate mixture 322, the method 300 may continue with a separating 330 of the precipitated, purified crystals (e.g., perovskite crystals) from the liquid phase of the intermediate mixture 322. The original impurities contained in the halide perovskite precursors (302A and/or 302B) have been transferred to the liquid phase of the intermediate mixture 322, leaving a purified perovskite solid phase. The separating 330 provides a phase separation, resulting in a first effluent stream 332, the liquid phase of the intermediate mixture 322, containing at least a portion of the first liquid 304 (and/or any additives 314), and the impurities removed from the halide perovskite precursors (302A and 302B) and a stream of the purified solid precipitated perovskite crystals, referred to herein as a “first” halide perovskite 334. The separating 330 (phase separation) may be achieved by any unit operation suitable for separating a solid from a liquid, with examples including centrifugation, filtration, electrostatic separation, and/or decantation. In some embodiments of the present disclosure, a first halide perovskite 334 may still contain liquid and/or solid impurities (e.g., the first liquid 304, additives 314, trace metals, etc.), for example as residual material on the outer surfaces of the first halide perovskite 335 or at grain boundaries. However, the bulk material of the first halide perovskite 334 will typically be essentially free of trace metals. Any residual impurities on the outer surfaces of the first halide perovskite 334 may be removed in a removing 340 step, subsequent the separating 330 step. In some embodiments of the present disclosure, a removing 340 of any residual impurities, from a first halide perovskite 334 may be accomplished using a wash liquid 336, such as a liquid solvent having a low solubility for the first halide perovskite 334, with examples including an ether (e.g., diethyl ether, ethyl ether), toluene, chlorobenzene, methyl acetate, ethyl acetate, anisole, isopropyl alcohol, γ-butyrolactone, and/or dimethyl formamide. In some embodiments, the first perovskite 334 may be crushed or ground prior to the removing step 340 to facilitate the washing of the crystals, particularly at buried grain boundaries. As a result of the removing 340 step, a washed halide perovskite precursor, referred to herein as a second halide perovskite 342 may be formed and an effluent stream (not shown) composed of the wash liquid 336 and the removed impurities.

In some embodiments of the present disclosure, the second halide perovskite 342 may be subjected to a drying 350 step, which among other things, may completely remove any residual liquids from the second halide perovskite 343 to produce the final, targeted, relatively pure halide perovskite 354 and a second effluent stream 352 composed of the liquids removed by the drying 350. The resultant final purified and dried halide perovskite 354 may then be stored for future use as a precursor to make high-quality perovskite films for use in devices, where, among other benefits, extremely accurate measurements of the individual perovskite precursors (e.g., BX₂ and/or AX) are not necessary because the perovskite stoichiometry is self-selected in the purified halide perovskite 354 due to the thermodynamically favorable perovskite phase, rather than individual perovskite precursor phases (BX₂ and/or AX), during formation 320. In some embodiments of the present disclosure (not shown in FIG. 3), a method may include a particle size reducing step of the dried halide perovskite 354, where the purified and dried halide perovskite crystals 354 are reduced from a starting particles size range between about 0.1 mm and about 50 mm to a final particle size range between about 0.005 mm and about 0.5 mm. In some embodiments, of the present disclosure, this reduction in particle size may be achieved on the manufacturing scale using a ball-mill, a hammer-mill, and/or a grinder, and on the laboratory scale, using a mortar and pestle. Among other things, the particle size reduction of the final, purified halide perovskite 354 may enable the more rapid incorporation (i.e., dissolution) of the halide perovskite 354 into a liquid (i.e., ink) for solution processing to fabricate the final desired halide perovskite film, and/or to enable more rapid vaporization of the halide perovskite 354 when utilizing vapor-phase processing methods to synthesize the final desired halide perovskite film. The purified halide perovskite 354 enables faster and more scalable manufacturing methods and the input of lower purity perovskite precursor material than direct use of individual perovskite precursor material.

In some embodiments of the present disclosure, a final purified halide perovskite synthesized as described above may have a composition characterized by the lack of impurities, which may be characterized by, among other things, its optoelectronic properties such as photoluminescence lifetime, carrier mobility, and/or photoluminescence efficiency.

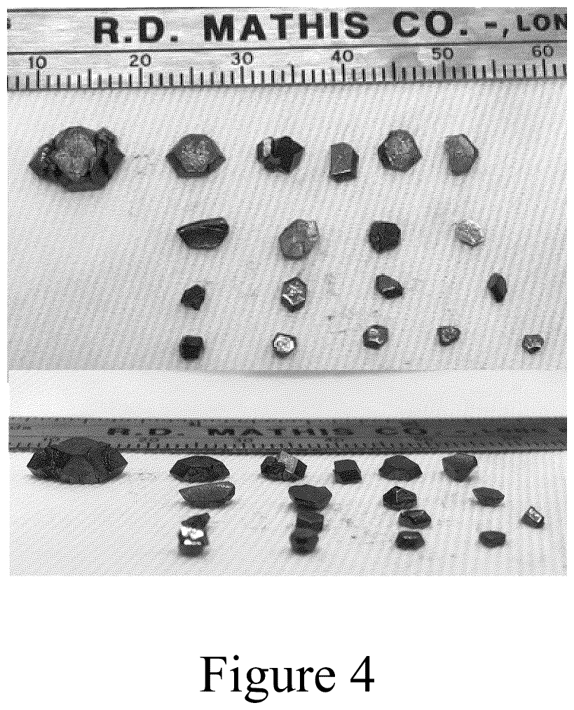

FIG. 4 illustrates examples of purified halide perovskites, synthesized by the methods described above, according to some embodiments of the present disclosure. These include various bulk ABX₃ crystals, with specific examples shown including Cs_{0.05}FA_{0.87}MA_{0.08}PbI_{2.76}Br_{0.24}, CsPbI₃, FAPbI₃, FAPbBr₃, which have all been synthesized according to the methods described herein. By having the desired stoichiometry of the final targeted perovskite film, these precursors have the advantage of eliminating weighing errors and/or errors in the stoichiometries of the individual perovskite precursors; e.g., AX and BX₂ salts. Examples of AX include one or more of methylammonium iodide (MAI), formamidinium iodide (FAI), cesium iodide (CsI), methylammonium bromide (MABr), formamidinium bromide (FABr), butylammonium iodide (BAI), phenethylammonium iodide (PAI), etc. and examples of BX₂ include one or more of PbI₂, PbBr₂, PbCl₂, SnI₂, SnBr₂, SnCl₂ etc. Thus, as described above, targeted final perovskite thin films may be formed by dissolving the bulk purified ABX₃ perovskite crystals obtained by the method described above in solvents to form inks for solution processing and/or may be used as a dry precursor for vapor deposition approaches, such as thermal evaporation (including flash evaporation or close-space sublimation). Of particular value, the methods described herein enable the use of low-grade PbI₂ sources to form high-performing, stable perovskite devices, which has historically been unachievable using the same low-grade PbI₂ in incumbent manufacturing methods.

The methods described herein enable, among other things, the ability to self-select the desired stoichiometry of the A, B, and X ions; e.g. ABX₃ stoichiometry. Without wishing to be bound by theory, bulk crystallization is closer to a thermodynamically driven process than rapid quenching during thin film formation. Thermodynamically, an ABX₃ crystal is the lowest energy form of perovskite materials and a slowly grown crystal through bulk crystallization will selectively form a stoichiometric ABX₃ solid while excluding “off-stoichiometric” components. In contrast, a quench method may be defined as a kinetic process and off-stoichiometries in the solvent may show up in the resultant perovskite film as defects. This means that bulk crystallization is not sensitive to small errors in weighing salts while the traditional mixed salt approach can be very sensitive. In addition, the perovskite precursors used to synthesize a desired final perovskite film are typically mixed based on mass and their assumed stoichiometry. Lead iodide, in particular, can have a large range of lead to iodine ratios. The thermodynamic nature of bulk crystallization, by utilizing the methods described herein, will essentially “automatically” and without error self-select the desired stoichiometry, e.g., ABX₃, even when utilizing off-stoichiometry perovskite precursor salts, such as low-grade PbI₂. This in turn may result in reduced batch-to-batch variability arising from variable feedstocks, faster processing times, and increased capacity for a given set of manufacturing equipment. In addition, the perovskite precursors resulting from the methods described herein may have improved stability (i.e., longer shelf life) and or less or no colloidal heterogeneities.

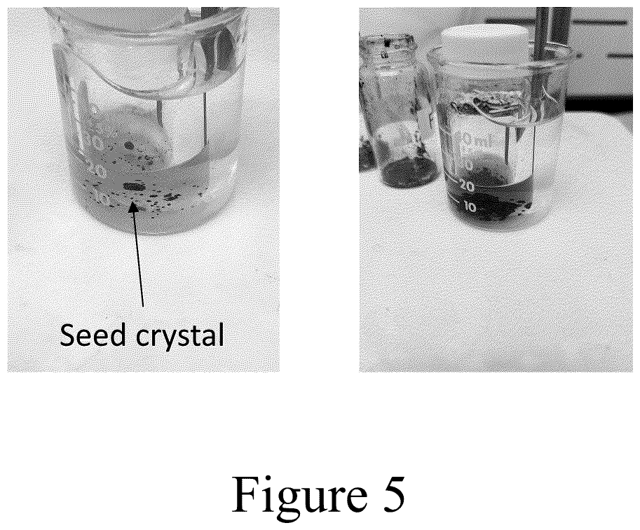

Exemplary experimental method: Precursor salts targeting a final perovskite defined by Cs_{0.05}FA_{0.87}MA_{0.08}PbI_{2.76}Br_{0.24} were weighed out: formamidinium iodide (FAI, Greatcell): 898 mg; methylammonium bromide (MABr, Greatcell): 54 mg; cesium iodide (CsI, Sigma-Aldrich): 78 mg; lead bromide (PbBr₂, Sigma Aldrich, 99.999%): 179 mg; and lead iodide (PbI₂, Sigma-Aldrich, 99%): 2538 mg. This mixture of starting halide perovskite precursors was subsequently dissolved in 5 ml gamma-butyrolactone (GBL) by stirring at 50° C. for 2 hours, resulting in a starting mixture. Next, an additive of 2 vol % formic acid (FAH) was 25 introduced to the mixture (to break up colloids to increase the concentration of free ions in the solution), followed by stirring for another 10 minutes. This mixture was then filtered using 0.2 μm nylon filter into a flat bottom cylindrical glass container to remove any insoluble material from the precursor feedstocks and large colloidal aggregation which could act as nucleation sites and likely sequester anionic impurities. Next, the solubility of the precursors was lowered by heating the mixture to a temperature of about 60° C., with the temperature maintained for about one hour. This initial step ensures that the crystal solution is at the correct starting temperature before beginning a controlled ramp. Subsequently, a temperature ramp was performed to about 95° C. at a ramp rate of about 5° C./hr. The mixture was held at 95° C. for about 10 hours (although much shorter times are expected to be sufficient; e.g., less than 5 hours or less than 1 hour), during which time the purified target halide perovskite precursor crystals formed (i.e., precipitated). Next, the precipitated perovskite precursor crystals were removed through filtration. The resultant intermediate perovskite crystals were subsequently washed in a two-step process, first using GBL wash step, and second using a diethyl ether (DEE) wash step. Next, the washed halide perovskite crystals were dried by exposing them to a nitrogen stream (N₂). The dried halide perovskite crystals were subsequently ground using a mortar and pestle for size reduction, which helps expose grain boundaries in the subsequent wash and the smaller size will ultimately improve solubility to form perovskite inks. The smaller particles of halide perovskite crystals were then washed in a second washing step, by contacting them with DEE in a Buchner funnel to remove residual reaction solvent. A subsequent drying step may be performed depending on the vapor pressure of the solvent(s) used in the washing steps. FIG. 5 illustrates the use of seed crystals (a solid additive 314), in this case an already purified halide perovskite crystal Cs_{0.05}FA_{0.87}MA_{0.08}PbI_{2.76}Br_{0.24} to initiate the forming process 320 (left) and a point later in time after substantially all of the precipitation had occurred (right). The dried final purified halide perovskite crystals (ABX₃) where stored as a solid in a glovebox and dissolved in a solvent mixture of dimethylformamide (DMF) and N-methylpyrolidone (NMP) to form an ink before device fabrication.

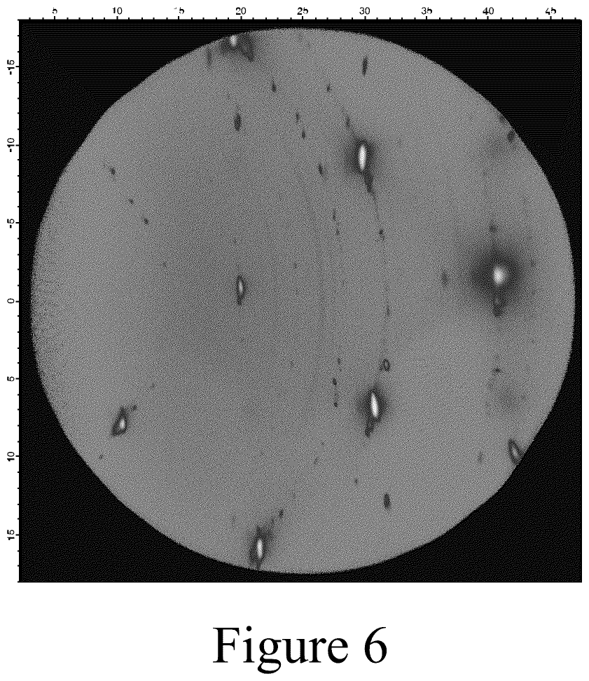

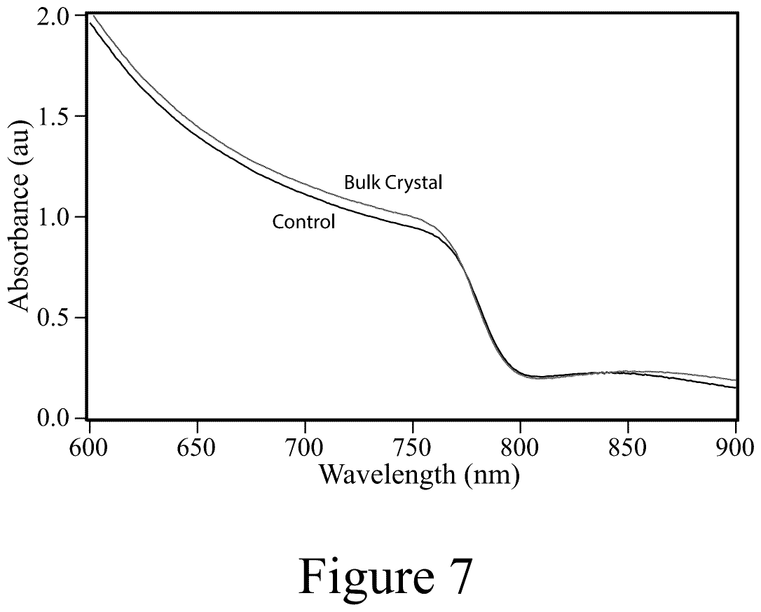

FIG. 6 illustrates XRD characterization of the resultant bulk halide perovskite crystal (Cs_{0.05}FA_{0.87}MA_{0.08}PbI_{2.76}Br_{0.24}) resulting from the unground crystals in the experiment described above (i.e., materials shown in FIG. 5). The diffraction pattern suggests a highly oriented, large-grain polycrystalline bulk. FIG. 7 illustrates UV-Vis data of a control film of perovskite material, Cs_{0.05}FA_{0.87}MA_{0.08}PbI_{2.76}Br_{0.24}, formed by a “traditional” (control) method and also using the bulk crystallization method as described herein (labeled “bulk-crystal”). The absorption edge is identical between the two samples which indicates that they have the same bandgap and that a substantially similar composition was maintained through the bulk-crystallization method. This is somewhat surprising because mixed single-crystals have not been reported and it was originally expected that certain A-site materials (MA, FA, Cs) might be excluded during the bulk crystal growth, however, control of the mixed stoichiometry was successfully maintained.

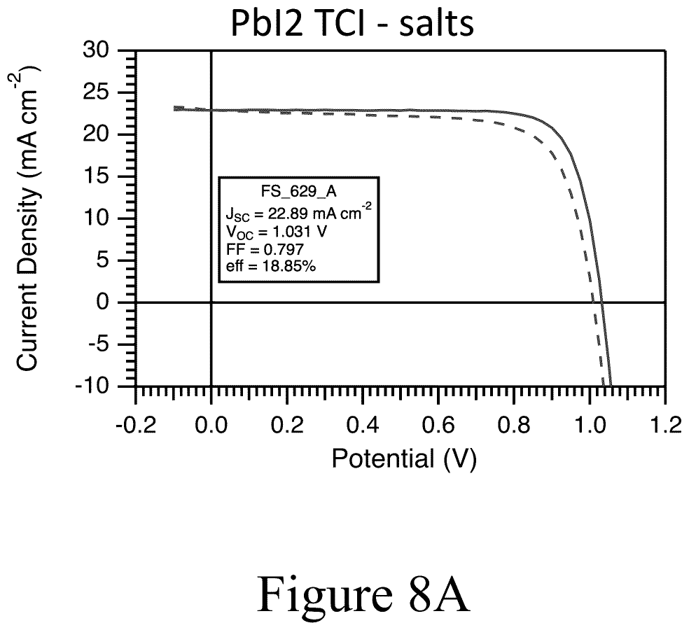

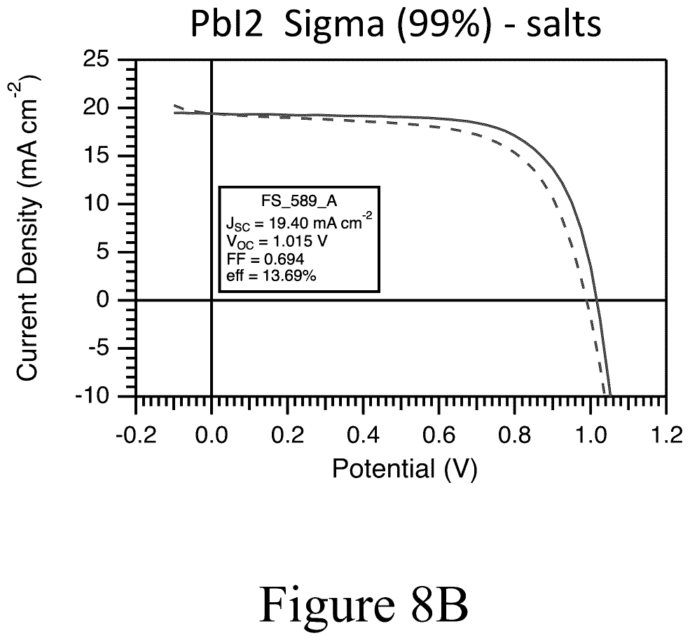

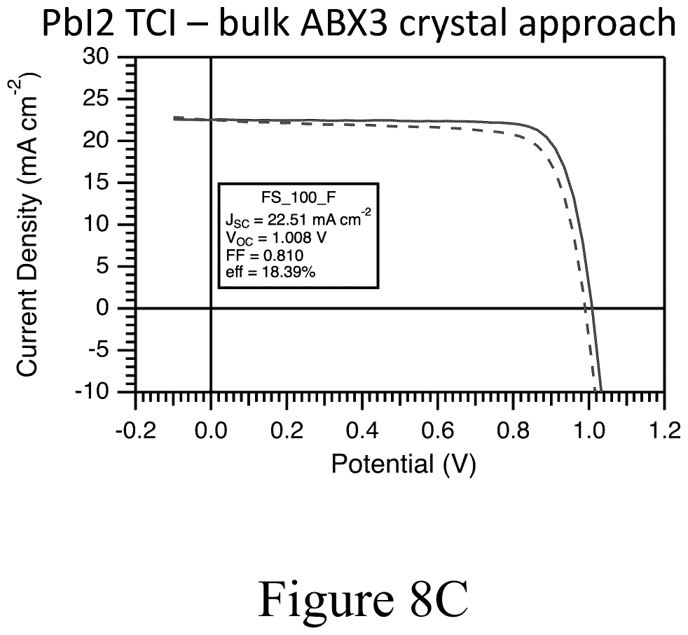

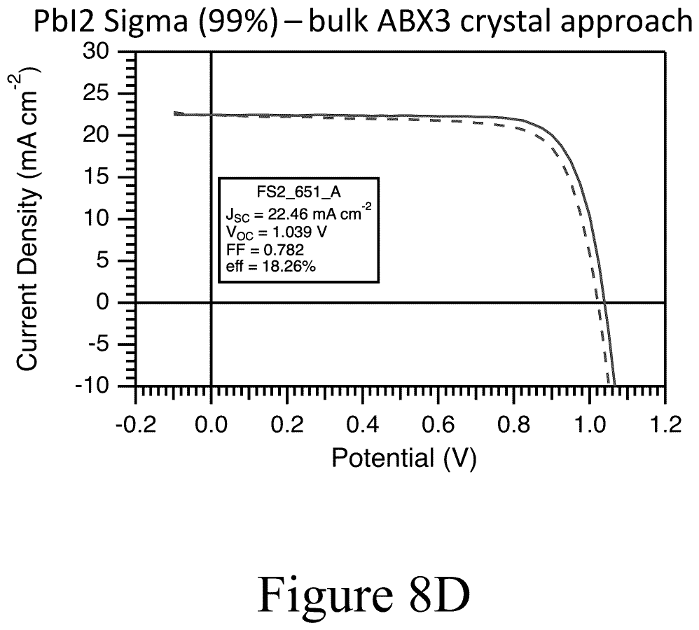

FIGS. 8A-8D illustrate a comparison of current-voltage device performance metrics (forward to reverse bias sweep shown in solid lines and reverse bias to forward bias sweep in dashed lines) for devices using perovskite films (Cs_{0.05}FA_{0.87}MA_{0.08}PbI_{2.76}Br_{0.24}) and architecture: ITO/PTAA/Perovskite/C₆₀/BCP/Ag fabricated using a traditional method (see FIGS. 8A and 8B) of inks utilizing a mixture of precursor salts to the method described herein using a single perovskite precursor containing all of the individual elements (see FIGS. 8C and 8D), according to some embodiments of the present disclosure. FIGS. 8A and 8C illustrate results obtained using high-quality and high-cost 99.99% PbI₂ from TCI chemicals, which has been developed specifically for perovskite precursors, and FIGS. 8B and 8D illustrate results obtained using a 99% purity low-grade PbI₂ from Sigma Aldrich. The traditional method (see FIGS. 8A and 8B) using high quality PbI₂ resulted in perovskite films that performed very well. However, the traditional mixed salt method using the low-grade PbI₂ resulted in films that performed very poorly. Referring again to FIGS. 8C and 8D, these results illustrate that regardless of the quality of the starting PbI₂(either high-quality 99.99% TCI PbI₂ or low-grade 99% Sigma Aldrich PbI₂), the method described herein using the bulk crystallization utilizing a purified single halide perovskite as the precursor resulted in devices having excellent performance metrics. These results were verified by reproducing these results four times.

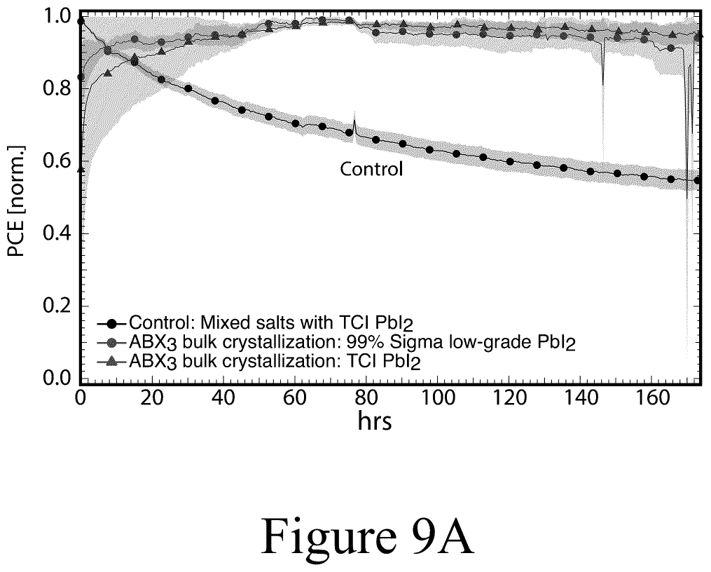

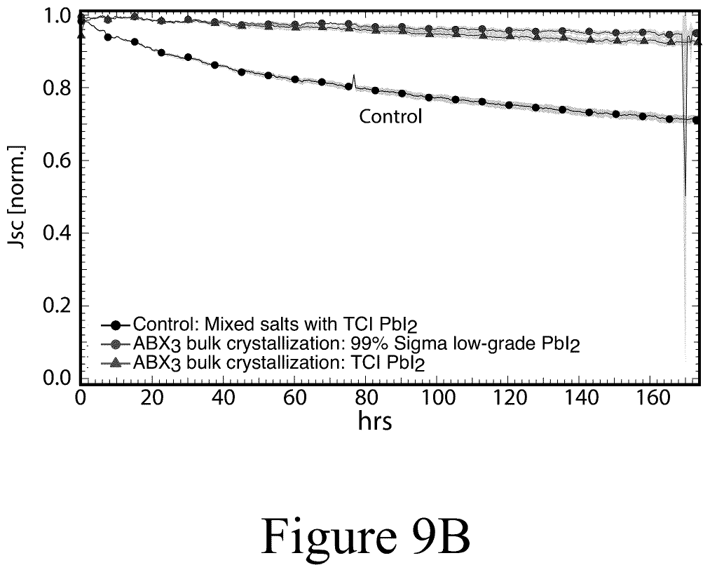

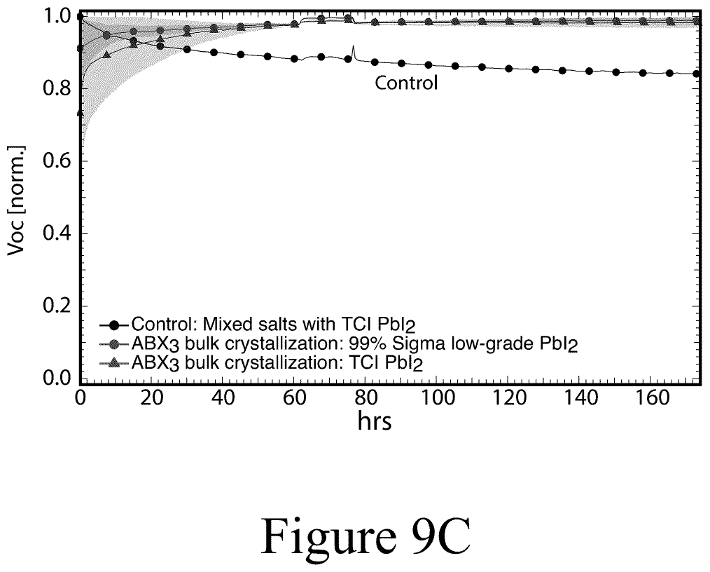

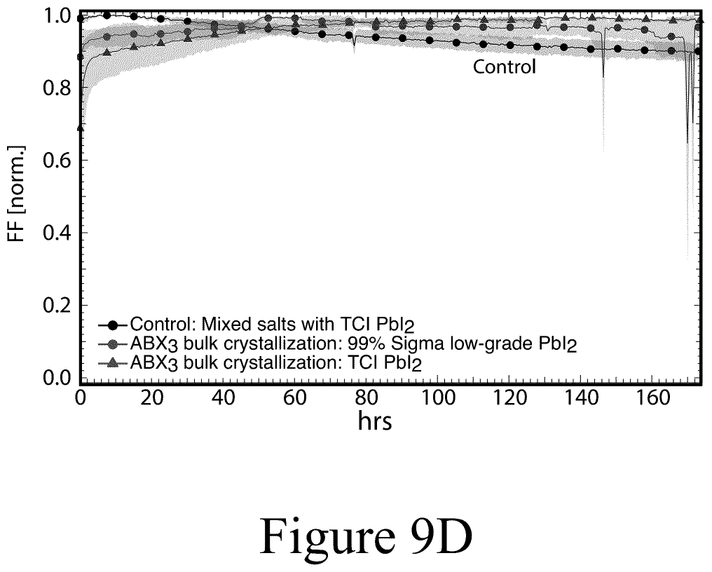

FIGS. 9A-9D illustrate stability data of devices with the architecture: (ITO/PTAA/Perovskite/C₆₀/BCP/Ag) constructed with perovskite films fabricated using either the “traditional” mixed salt approach (black) with TCI PbI₂ and devices made by the bulk-crystallization approach described herein with TCI PbI₂ and low-grade Sigma Aldrich PbI2. The devices were tested near their maximum power point with periodic current-voltage sweeps to obtain operational figures of merit at 70 degrees Celsius under a nitrogen atmosphere at 0.77 suns illumination intensity. These degradation conditions are considered very harsh relative to the state-of-the-art in the field. Both devices fabricated with the ABX₃ bulk crystallization approach, the method described herein, are significantly more stable than the control device made using the traditional mixed perovskite precursor approach.

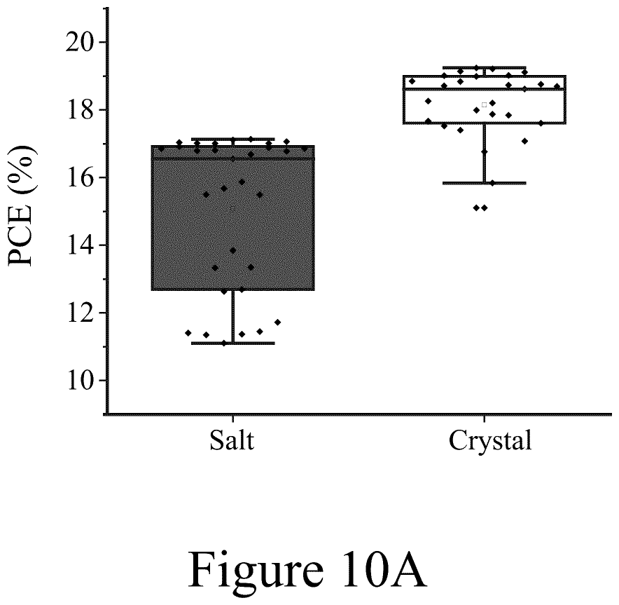

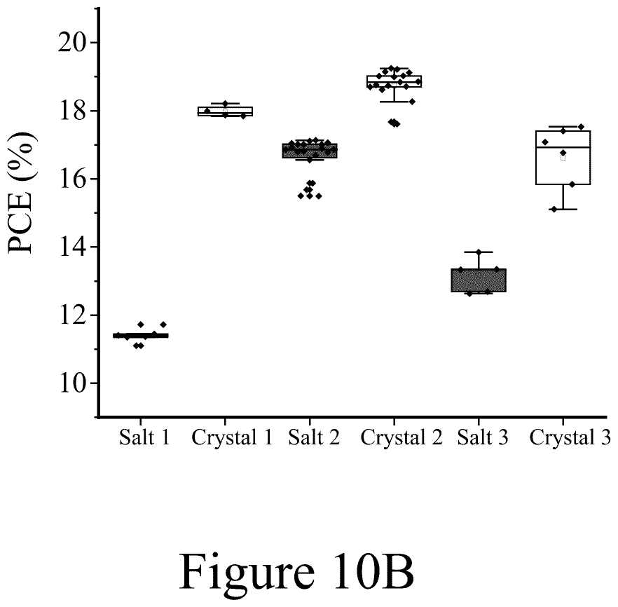

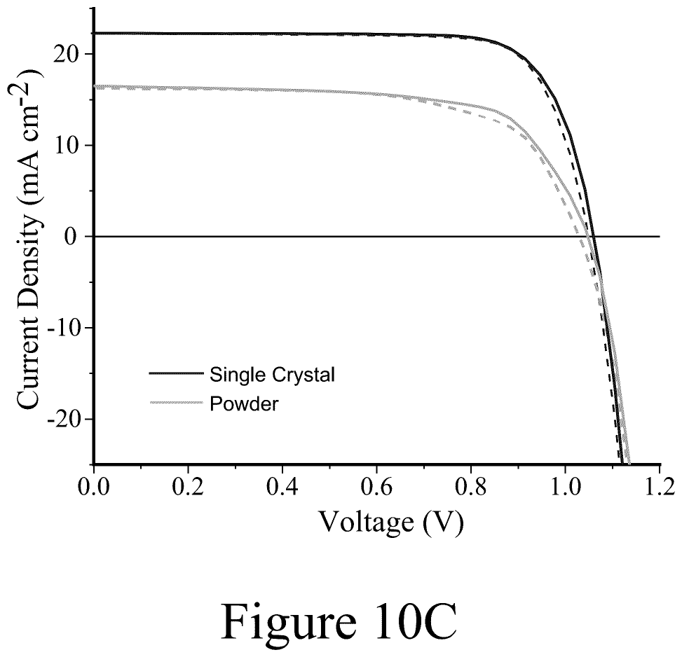

FIGS. 10A and 10B illustrate device performance made by the methods described herein, according to some embodiments of the present disclosure. FIG. 10A illustrates aggregated data resulting from three batches of devices made from 99% PbI₂ (Sigma Aldrich). The “Salt” data refers to three devices constructed using untreated 99% pure PbI₂ to form the perovskite active layer and the “Crystal” data refers to three devices constructed using perovskite crystals as a precursor, generated by the methods described herein to form the perovskite active layer. Each batch was made independently, on separate days. The p value from an unpaired t-test is <0.0001, indicating the power conversion efficiency improvement from the bulk crystallization approach is extremely statistically significant. FIG. 10B illustrates the individual data sets used to generate the aggregated data illustrated in FIG. 10A. The data of FIG. 10B illustrate that despite process variability between batches, the improvement from the “bulk crystallization” approach is reproducible and substantial. FIG. 10C illustrates J-V performance curves of the best performing devices constructed using perovskite absorber layers synthesized using the single perovskite crystal precursor generated using the methods described herein versus devices having perovskite layers using the typical powder perovskite precursors. Both curves correspond to the devices labeled “Salt 1” and “Crystal 1” in FIG. 10B. The bulk crystallization methods described herein, results in devices having substantially purified perovskite active layers, resulting in substantially improves current density and fill factor in the final complete device stack.

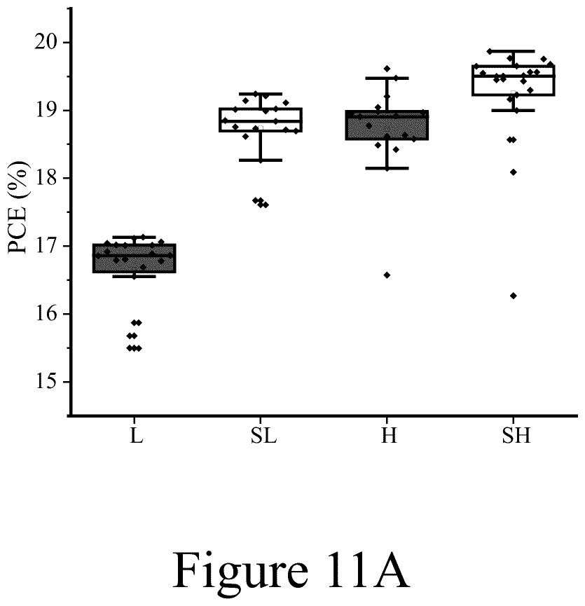

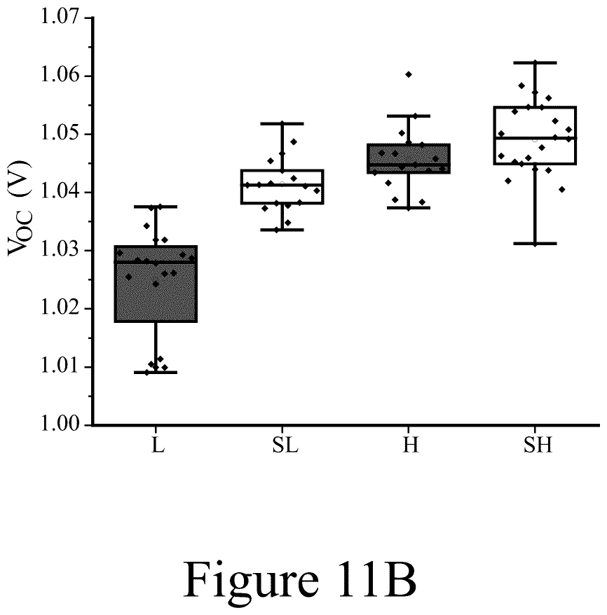

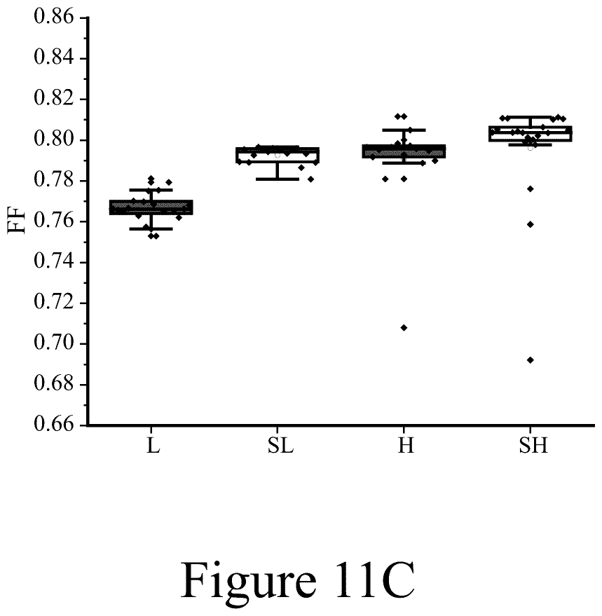

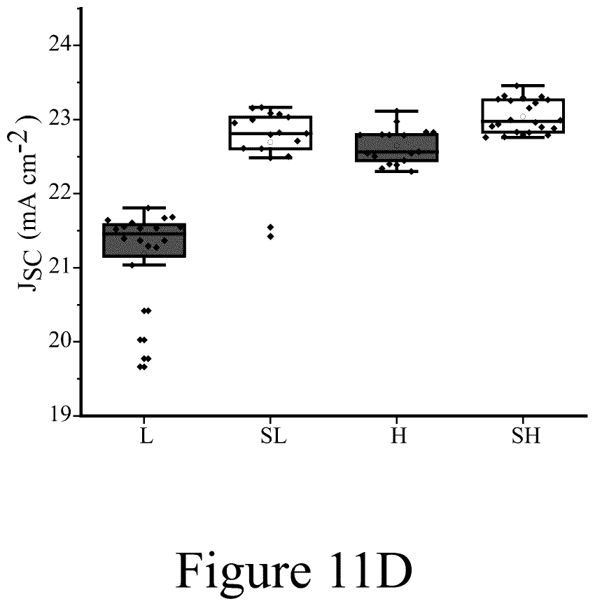

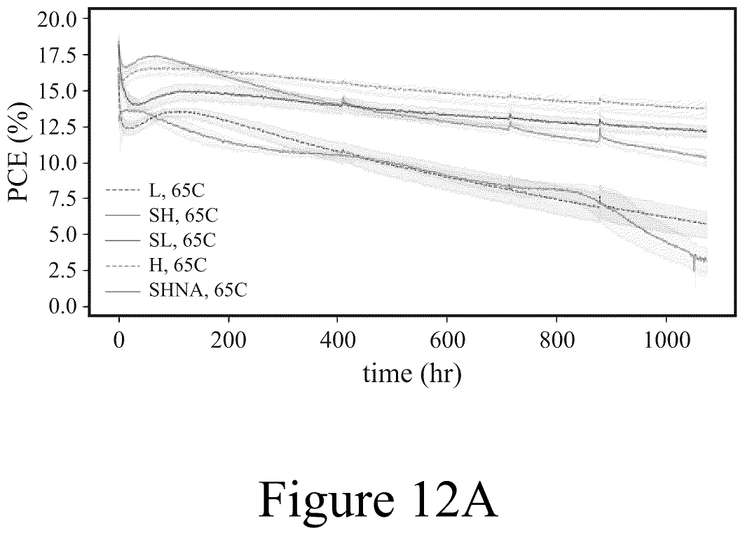

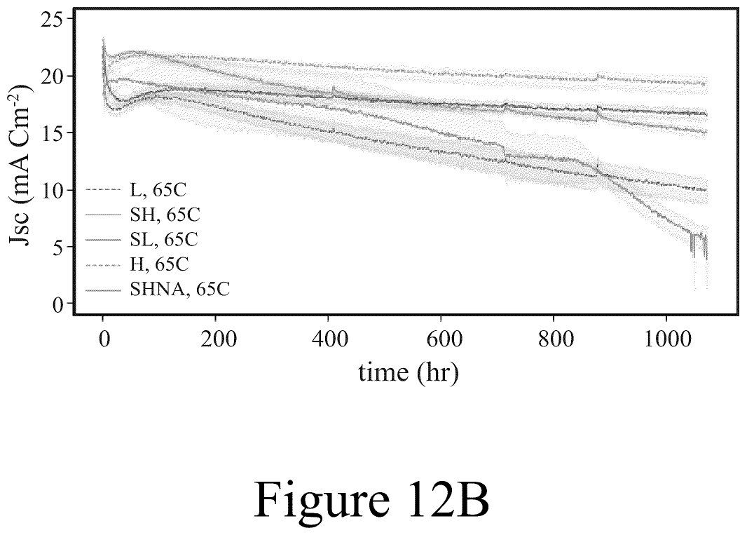

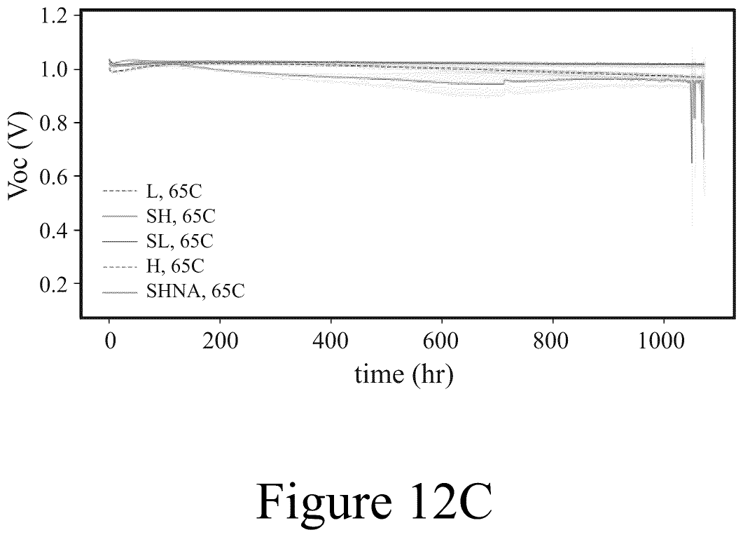

FIGS. 11A-11D illustrate the performance metrics of devices made using different perovskite precursors/starting materials, according to some embodiments of the present disclosure. (L=low purity salt perovskite precursors; SL=purified single crystal perovskite precursors generated low purity salt perovskite precursors by the methods described herein; H=high purity salt perovskite precursors; and HL=purified single crystal perovskite precursors generated high purity salt perovskite precursors by the methods described herein.) These figures illustrate that the “bulk crystallization” methods described herein to synthesize purified perovskite crystals to be used in solution processing (or vapor phase processing) to generate perovskite active layers in solar cell devices can dramatically increase at least the starting device performance of the low purity salts (99% PbI₂, Sigma Aldrich) to levels demonstrated by devices constructed with perovskite active layers synthesized using high purity salts (99.99%, TCI Chemicals). In a manufacturing environment, this could enable the use of lower purity or recycled feedstocks. There is no statistically significant difference between the SL and H performance. Furthermore, “bulk crystallization” methods describe herein result in devices having improved performance when comparing devices using perovskite precursors generated from high purity salts to make the perovskite active layer versus devices having perovskite active layers generated using just the untreated high purity (p 0.0032). Such performance improvements are evident across all key device parameters.

FIGS. 12A-12D illustrate stability data of devices made using different perovskite precursors/starting materials, according to some embodiments of the present disclosure. These figures validate that the improved initial performance metrics described above for FIGS. 11A-11D are maintained over time. The devices made from the bulk crystallization method show reduced degradation rates in power conversion efficiency during aging under N₂ over 1,000 hours at 70° C., under 0.7 sun illumination, with quasi-max power point tracking.

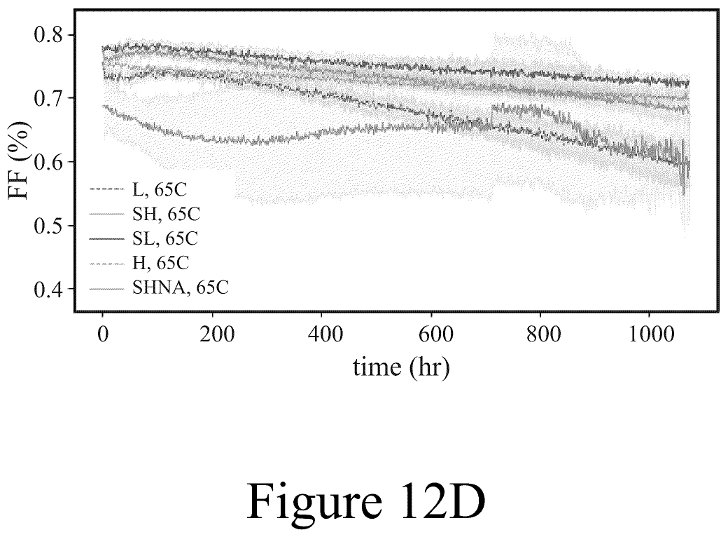

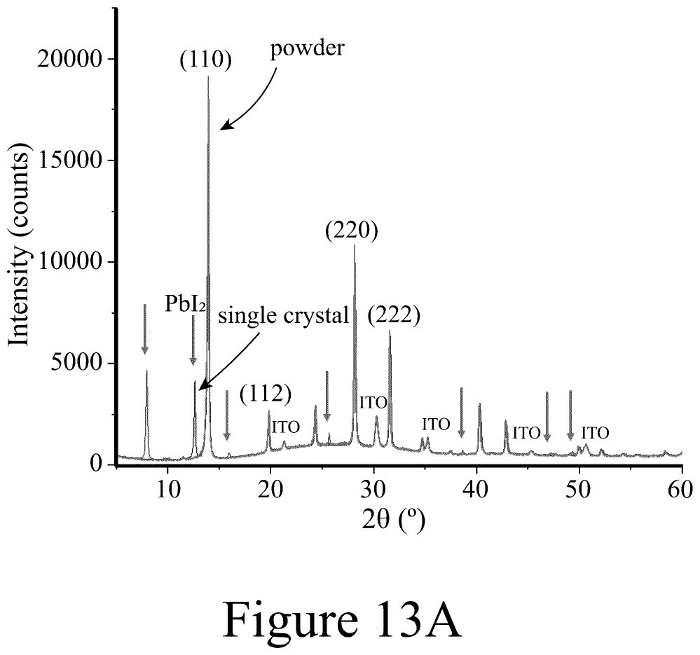

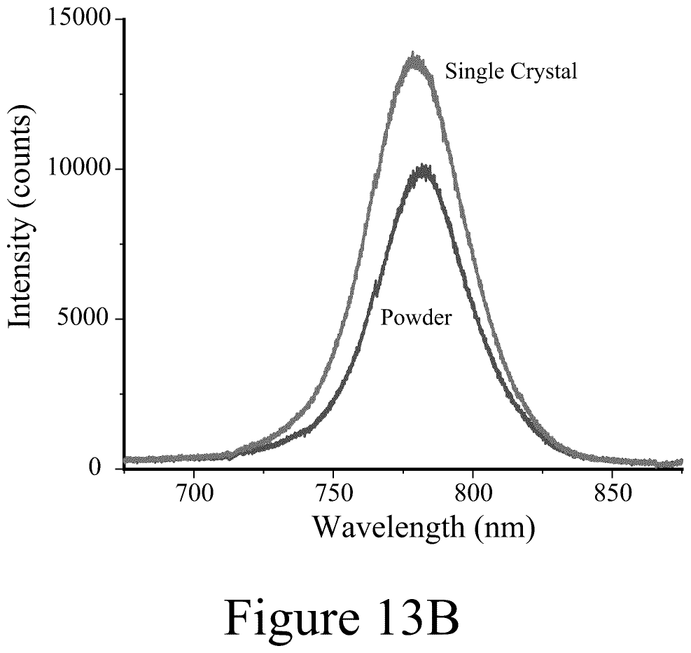

FIGS. 13A and 13B illustrate XRD and PL emission data of perovskite films generated from standard salts and from perovskite precursor crystals made from standard salts via the methods described herein. These data illustrate that the bulk crystallization methods described herein may change the perovskite stoichiometry, potentially resulting changes in stability of the final perovskite-containing devices. For example, cesium iodide has a much lower solubility than lead iodide in GBL, which may lead to differences between the composition of perovskite films made from bulk crystallization and from precursor salts. XRD does not reveal substantial peak shifts, which would occur with varying lattice incorporation of Cs⁺ between the powder and single crystal, for example. The bandgap, taken from the PL emission, is also similar (778 vs 782 nm), indicating no substantial compositional differences between the powders and single crystals.

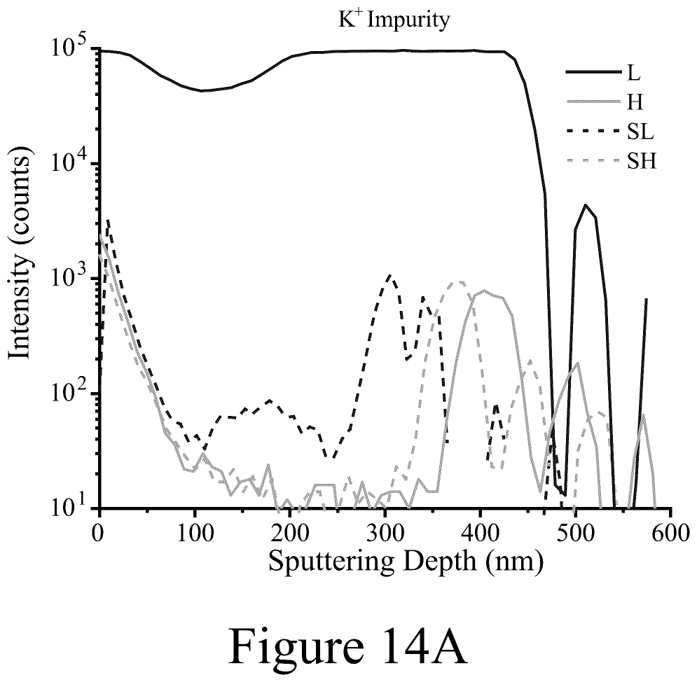

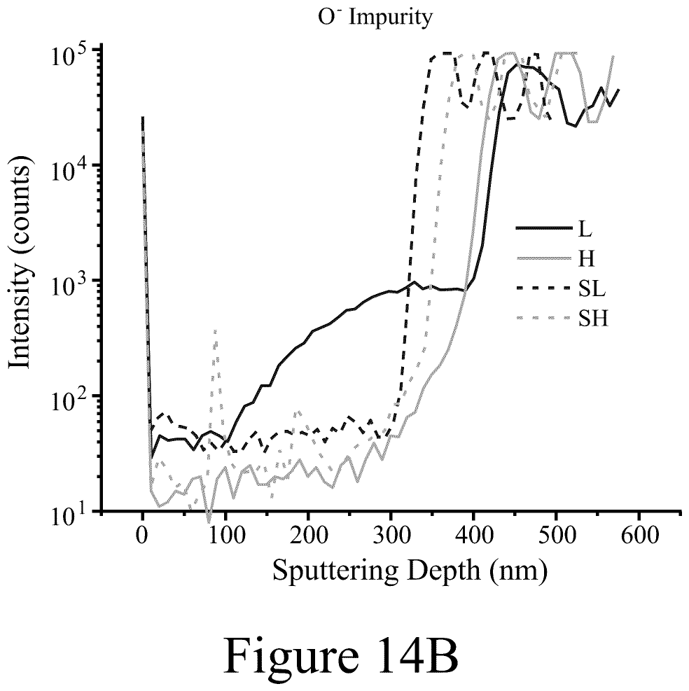

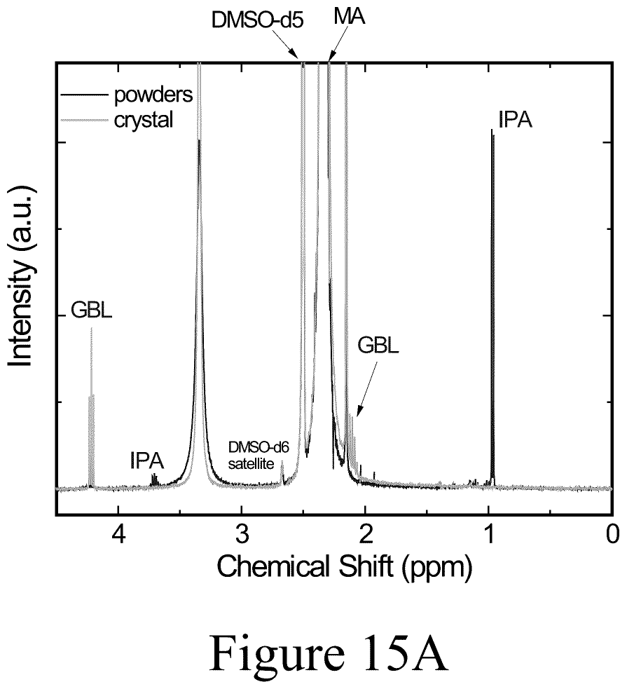

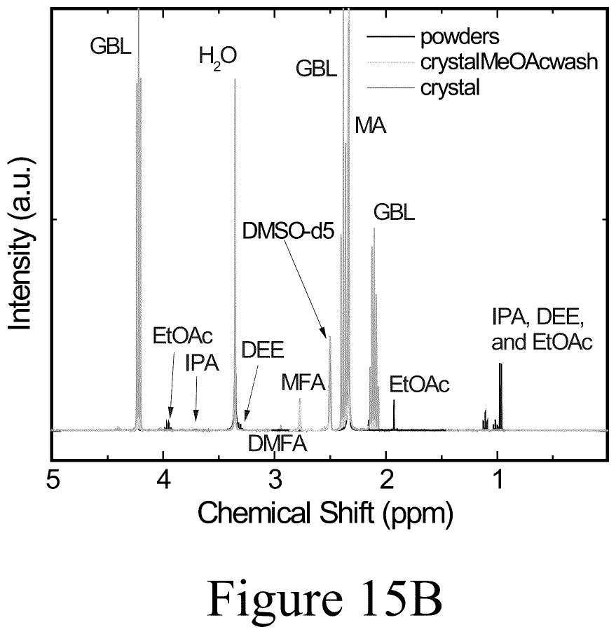

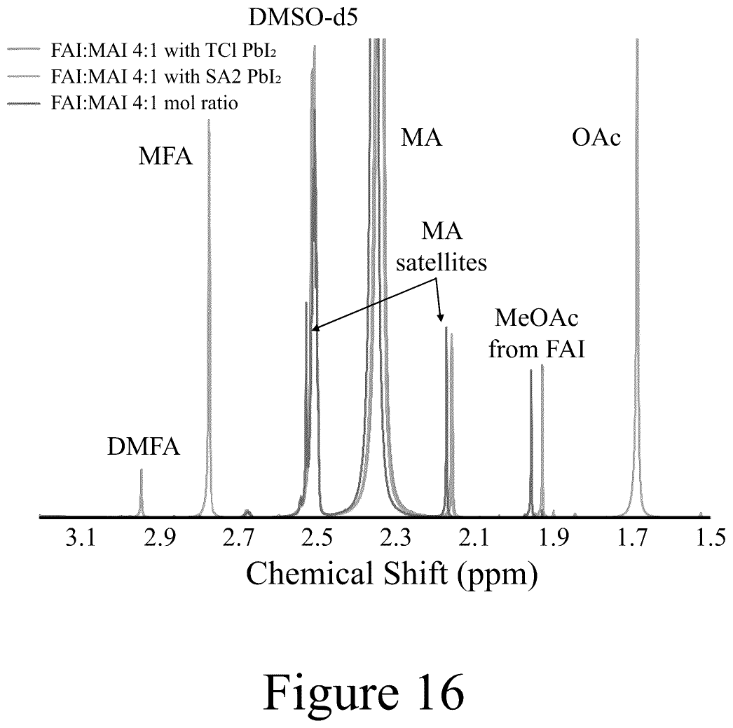

FIGS. 14A and 14B illustrate ToF-SIMS results of impurities of starting of starting perovskite precursors versus treated perovskite precursors, according to some embodiments of the present disclosure. The bulk crystal method described herein reduces K⁺ impurity SIMS intensity by 2-3 orders of magnitude, relative to the as-received salts (99% PbI₂, Sigma). 0—impurity signal are also reduced by ˜1 order of magnitude. The bulk crystal method also removes solvent impurities present in the as-received precursor salts (isopropyl alcohol impurity shown here), as illustrated in FIG. 15A. Residual GBL is present on the crystal surface from the growth process but is not considered an impurity because it functions as a good, coordinating solvent in the perovskite ink. Referring to FIG. 15B, here, ethyl acetate (EtOAc), isopropyl alcohol (IPA), and diethyl ether (DEE) impurities were successfully removed from as-received FAI by the salt precursor treatment method described herein to yield perovskite crystals to be used as precursors for the forming of perovskite active layers. Residual GBL remained on the crystal surface. The lightly shaded trace shows residual GBL. GBL can be washed from the crystal surface with methyl acetate. The large H₂O signal is from the DMSO-d6 NMR solvent and does not suggest H₂O as a substantial impurity in the crystals. Solvent impurities present in as-received salts can catalyze undesirable chemical reactions in the perovskite. For example, FIG. 16 demonstrates that OAc impurity, which is present in the 99% PbI₂ (Sigma) but not in the 99.99% PbI₂ (TCI Chemicals) accelerates the reaction between the methylammonium and formamidinium cations, generating N-methylformamidinium (MFA) and N, N′-dimethylformamidinium (DMFA). Thus, the methods described herein provide meaningful manufacturing benefits.

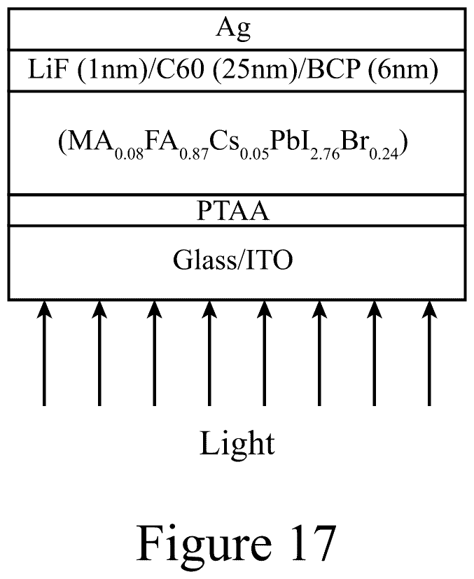

FIG. 17 illustrates an exemplary stack that was fabricated using perovskite precursors synthesized using the methods described herein, according to some embodiments of the present disclosure. ITO coated glass was sonicated sequentially in deionized water, acetone, and isopropyl alcohol before treatment with UV ozone for 10 minutes immediately before film deposition. First, poly(triarylamine) (PTAA) at a concentration of 2 mg ml⁻¹ in toluene was spin coated at 6k rpm for 30 seconds before annealing at 100° C. for 10 minutes. Next, the perovskite precursor (1.2 M in 8:1 DMF:NMP) was deposited by spin coating at 5k rpm for 35 seconds, with N₂ “quenching” used to induce nucleation with a nitrogen gun position ˜5 cm above the substrate. During the last 25 seconds of spin coating, N₂ gas at ˜80 psi was flowed over the substrate, then the perovskite layer was annealed at 100° C. for 30 minutes. Next, selective contacts were sequentially evaporated under vacuum with pressure <10⁻⁶ torr. 1 nm LiF was thermally evaporated at a deposition rate of 0.1 Å/s. 25 nm C₆₀ fullerene was thermally evaporated at a rate of 0.2-0.5 Å/s. 6 nm BCP was thermally evaporated at a rate of 0.1 Å/s. 100 nm Ag was thermally evaporated at a rate of 0.5-2.0 Å/s. In device set #3 (see FIG. 10B), which was used for the 1,000 hour stability test (see FIGS. 12A-12D), BCP was replaced with 7 nm SnO₂ deposited by atomic layer deposition. The Ag was replaced by 4 nm Cr and 100 nm Au.

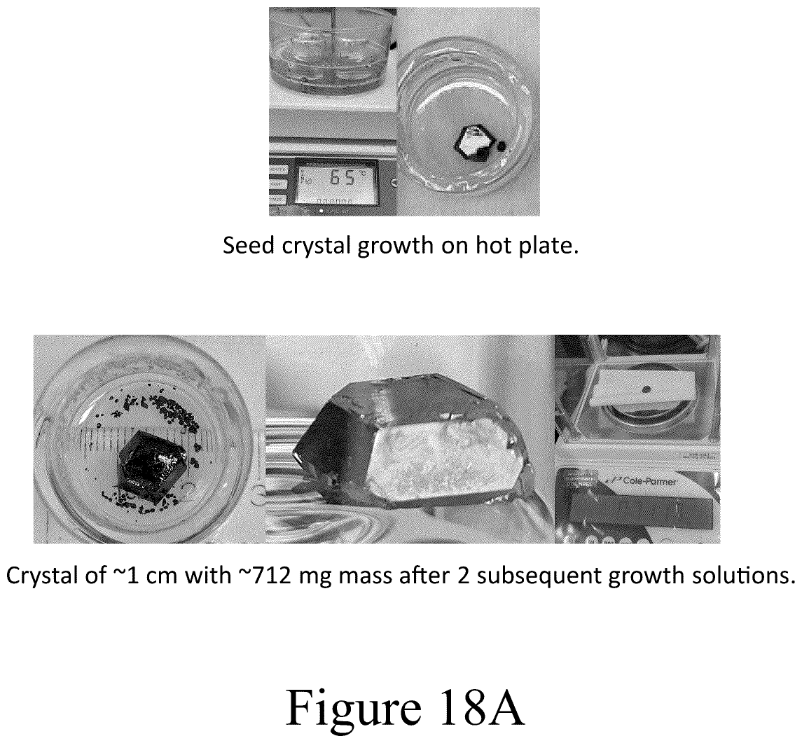

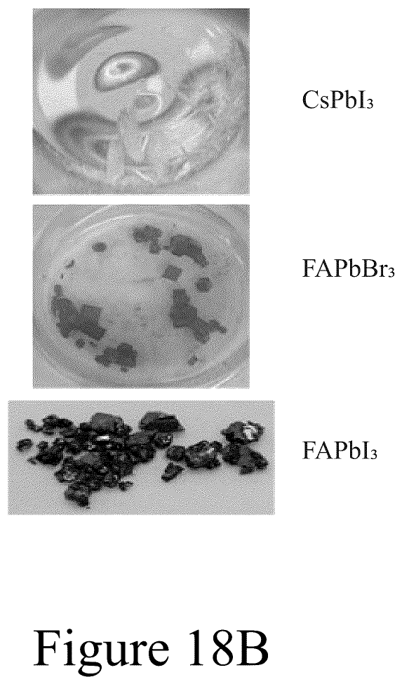

FIG. 18A illustrates perovskite crystals made by the methods described herein, to be used as precursors for generating improved perovskite active layers in devices (e.g., solar cells), according to some embodiments of the present disclosure. These crystals were generated to target a perovskite composition of MA_{0.08}FA_{0.87}Cs_{0.05}PbI_{2.76}Br_{0.24}. The following precursor salts were dissolved in 1 mL of GBL to generate the perovskite precursor crystal: MABr 10.7 mg, CsI 15.6 mg, PbBr₂ 35.3 mg, FAI 179.5 mg, and PbI₂ 509 mg. The salts/BGL mixture was then stirred for about 1 hour in ambient conditions. The resultant solution was then filtered through a 0.2 um PTFE syringe filter and added to flat bottom glass vessels. After about 90 minutes, a seed crystal having the composition MA_{0.08}FA_{0.87}Cs_{0.05}PbI_{2.76}Br_{0.24} was transferred into 2 mL of fresh precursor solution preheated to 85° C. and the solution was allowed to form perovskite crystals for about 3 hours. The resultant, now purified, perovskite crystal was then transferred a final time into 5 mL of fresh precursor solution, yielding a single crystal of ˜1 cm diagonal dimension. In other words, a two-step process was used in this example: A first step to form a first purified perovskite crystal, followed by a second step where that crystal was used as a seed crystal to increase its size. Before being used to produce perovskite active layers in devices, the resultant crystal was washed three times by submersing the crystal in about 1 mL methyl acetate with gentle agitation. The crystal was subsequently ground into a powder before dissolution in NMP-DMF solvent for thin films. FIG. 18B illustrates other perovskite crystals made by the methods described herein, CsPbI₃, FAPbBr₃, and FAPbI₃ perovskite crystals.

### Examples

Example 1. A method comprising: preparing a mixture by dissolving at least two halide perovskite precursors in a first liquid; forming a halide perovskite crystal in the mixture by lowering a solubility limit of at least one of the halide perovskite precursors; and separating the halide perovskite crystal from the mixture, wherein: at least one of the halide perovskite precursors contains an impurity, and the halide perovskite crystal is substantially free of the impurity.

Example 2. The method of Example 1, wherein the halide perovskite crystal has a first average characteristic length between about 0.1 mm and about 50 mm.

Example 3. The method of either Example 1 or Example 2, wherein the halide perovskite crystal comprises at least one of a 3D crystal, a 2D crystal, or a 1D crystal.

Example 4. The method of any one of Examples 1-3, wherein: the halide perovskite crystal has a chemical formula comprising at least one of ABX₃ or A₂BX₄, A is a monovalent cation, B is a divalent metal cation, and X is a monovalent halide anion, and together, the at least two precursors comprise A, B, and X.

Example 5. The method of any one of Examples 1-4, wherein A comprises at least one of an alkali metal, an alkylammonium, a phenylalkylammonium, an arylammonium, an allylammonium, or formamidinium (FA).

Example 6. The method of any one of Examples 1-5, wherein the alkali metal comprises at least one cesium, rubidium, or potassium Example 7. The method of any one of Examples 1-6, wherein the alkylammonium comprises at least one of methylammonium (MA), butylammonium (BA), dimethylammonium (DA), or guanidinium.

Example 8. The method of any one of Examples 1-7, wherein the phenylalkylammonium comprises at least one of phenethylammonium (PEA), 4-fluoro-phenethylammonium iodide, or pentafluoro-phenethylammonium.

Example 9. The method of any one of Examples 1-8, wherein B comprises at least one of lead or tin.

Example 10. The method of any one of Examples 1-9, wherein X comprises at least one of iodide, bromide, chloride, or fluoride.

Example 11. The method of any one of Examples 1-10, wherein: the perovskite crystal comprises Cs_{z}(FAₓMA₁₋ₓ)_{1-z}Pb(Cl_{w}(I_{y}Br_{1-y})_{1-w})₃, 0≤w≤1, 0≤x≤1, 0≤y≤1, and 0≤z≤1.

Example 12. The method of any one of Examples 1-11, wherein w=0.

Example 13. The method of any one of Examples 1-12, wherein the perovskite crystal is about Cs_{0.05}FA_{0.87}MA_{0.08}PbI_{2.76}Br_{0.24}.

Example 14. The method of any one of Examples 1-13, wherein the halide perovskite crystal comprises at least one of MAPbI₃, MAFACsPbIBr, FAPbI₃, FAPbBr₃, MAPbBr₃, CsPbBr₃, CsPbI₃, (CH₆N)PbI₃, or (C₄H₁₂N)₂PbBr₄.

Example 15. The method of any one of Examples 1-14, wherein the halide perovskite precursors comprise BX₂ and AX.

Example 16. The method of any one of Examples 1-15, wherein BX₂ has a purity between about 95% and about 99.99% on a trace metals basis.

Example 17. The method of any one of Examples 1-16, wherein the X and B of BX₂ are at a ratio of X:B between about 1:1 and about 1.99:1.

Example 18. The method of any one of Examples 1-17, wherein the halide perovskite precursor AX has an assay purity between 90% and 98% on a trace metals basis.

Example 19. The method of any one of Examples 1-18, wherein the impurity comprises a metal.

Example 20. The method of any one of Examples 1-19, wherein the metal comprises at least one of Na, Mg, Al, Si, K, Ca, Cr, Mn, Fe, Co, Ni, Cu, Zn, Ag, Ba, Bi, Rh, Pt, or Pd.

Example 21. The method of any one of Examples 1-20, wherein the first liquid comprises at least one of a polar solvent or an ionic liquid.

Example 22. The method of any one of Examples 1-21, wherein the polar solvent is protic.

Example 23. The method of any one of Examples 1-22, wherein the protic polar solvent comprises water, methanol, or isopropanol.

Example 24. The method of any one of Examples 1-23, wherein the polar solvent is aprotic.

Example 25. The method of any one of Examples 1-24, wherein the aprotic solvent comprises at least one of acetonitrile, dimethylformamide, dimethylsulfoxide, methyl-2-pyrrrolidone, or 7-butyrolactone.

Example 26. The method of any one of Examples 1-25, wherein the ionic liquid comprises at least one of 1-butyl-3-methylimidazolium tetrafluoroborate, 3-methylimidazolium hexafluorophosphate, imidazolium tetrafluoroborate, 1-butyl-1-methylpiperidinium tetrafluoroborate, or 1-butyl-1-methylpiperidinium hexafluorophosphate.

Example 27. The method of any one of Examples 1-26, wherein the preparing and forming are performed in series.

Example 28. The method of any one of Examples 1-27, wherein the preparing and forming are performed in a single step.

Example 29. The method of any one of Examples 1-28, wherein the forming further includes providing an additive to the mixture.

Example 30. The method of any one of Examples 1-29, wherein the additive includes at least one of an organic acid, an inorganic acid, an ionic liquid, an oil, an acid, an antisolvent, or water.

Example 31. The method of any one of Examples 1-30, wherein the organic acid comprises at least one of formic acid, acetic acid, a hydrohalic, or a hypophosphorous acid.

Example 32. The method of any one of Examples 1-31, wherein the inorganic acid comprises at least one of HCl, HI, HBr, or BF.

Example 33. The method of any one of Examples 1-32, wherein the ionic liquid comprises at least one of BMIM:BF4 or BMIM:PF6.

Example 34. The method of any one of Examples 1-33, wherein the oil comprises at least one of a silicone oil or a petroleum-based oil.

Example 35. The method of any one of Examples 1-34, wherein the preparing is performed with the mixture at a first temperature between about 20° C. and about 180° C.

Example 36. The method of any one of Examples 1-35, wherein the forming is performed with the mixture at a second temperature that is different than the first temperature.

Example 37. The method of any one of Examples 1-36, wherein the second temperature is higher than the first temperature.

Example 38. The method of any one of Examples 1-37, wherein the second temperature is lower than the first temperature.

Example 39. The method of any one of Examples 1-38, wherein the second temperature is between about 20° C. and about 180° C.

Example 40. The method of any one of Examples 1-39, wherein the forming is induced by the addition of the additive.

Example 41. The method of any one of Examples 1-40, wherein the forming comprises at least one of evaporating at least a portion of the mixture, applying ultrasound to the mixture, applying a mechanical treatment to the mixture, an acoustical treatment of the mixture, a pressure treatment of the mixture, an electrical treatment of the mixture, or an electromagnetic treatment of the mixture.

Example 42. The method of any one of Examples 1-41, wherein, after the forming, the mixture comprises the halide perovskite crystal and a liquid phase comprising the impurity.

Example 43. The method of any one of Examples 1-42, wherein: the separating results in the separation of the mixture into the halide perovskite crystal as a solid stream and an effluent stream, and the effluent stream comprises the liquid phase and the impurity.

Example 44. The method of any one of Examples 1-43, wherein the liquid phase comprises the first liquid and the impurity.

Example 45. The method of any one of Examples 1-44, wherein the separating is performed by at least one filtration of the mixture or centrifugation of the mixture.

Example 46. The method of any one of Examples 1-45, further comprising after the separating, a removing from the halide perovskite crystal any remaining portion of the impurity.

Example 47. The method of any one of Examples 1-46, wherein the removing comprises contacting the halide perovskite crystal with a wash liquid.

Example 48. The method of any one of Examples 1-47, wherein the wash liquid comprises at least one of an ether or γ-butyrolactone.

Example 49. The method of any one of Examples 1-48, wherein the ether comprises at least one of diethyl ether or ethyl ether.

Example 50. The method of any one of Examples 1-49, further comprising, after the separating, drying the halide perovskite crystal.

Example 51. The method of any one of Examples 1-50, wherein the drying is performed after the removing.

Example 52. The method of any one of Examples 1-51, further comprising after the separating, reducing the particle size of the halide perovskite crystal to a second average particle length between about 0.005 mm and about 0.5 mm.

Example 53. The method of any one of Examples 1-52, wherein the reducing is performed using at least one of a ball-mill or a hammer-mill.

Example 54. The method of any one of Examples 1-53, wherein the reducing is performed after the drying.

Example 55. The method of any one of Examples 1-54, further comprising: after the separating, forming a halide perovskite film, wherein the forming utilizes the halide perovskite crystal as a precursor, and the perovskite film has substantially the same composition of A, B, and X as the halide perovskite crystal precursor.

Example 56. The method of any one of Examples 1-55, wherein the forming comprises at least one of a liquid deposition method or a vapor-phase deposition method.

Example 57. The method of any one of Examples 1-56, wherein the halide perovskite film is formed after the reducing.

Example 58. The method of any one of Examples 1-57, wherein the film contains N-methylformamidinium.

Example 59. The method of any one of Examples 1-58, wherein the film further comprises MA at a concentration between 0 wt % and 1 wt %.

Example 60. The method of any one of Examples 1-59, wherein the halide perovskite is characterized by the lack of impurities, as can be characterized by its optoelectronic properties such as photoluminescence lifetime or photoluminescence efficiency.

Example 61. A composition comprising: a halide perovskite comprising at least one of ABX₃ or A₂BX₄, wherein: A is a monovalent cation, B is a divalent metal cation, and X is a monovalent halide anion, and the halide perovskite further comprises N-methylformamidinium.

Example 62. The composition of Example 61, wherein the film further comprises methylammonium at a concentration between 0 wt % and 1 wt %.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure.

The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A method comprising:
preparing a mixture by dissolving at least two halide perovskite precursors in a first liquid;
forming a halide perovskite crystal in the mixture by lowering a solubility limit of at least one of the halide perovskite precursors; and
separating the halide perovskite crystal from the mixture, wherein:
at least one of the halide perovskite precursors contains an impurity, and
the halide perovskite crystal is substantially free of the impurity.

2. The method of claim 1, wherein the halide perovskite crystal comprises at least one of a 3D crystal, a 2D crystal, or a 1D crystal.

3. The method of claim 2, wherein:
the halide perovskite crystal has a chemical formula comprising at least one of ABX₃ or A₂BX₄,
A is a monovalent cation, B is a divalent metal cation, and X is a monovalent halide anion, and
together, the at least two precursors comprise A, B, and X.

4. The method of claim 3, wherein:
the perovskite crystal comprises Cs_{z}(FAₓMA₁₋ₓ)_{1-z}Pb(Cl_{w}(I_{y}Br_{1-y})_{1-w})₃,
0≤w≤1, 0≤x≤1, 0≤y≤1, and 0≤z≤1.

5. The method of claim 3, wherein the halide perovskite crystal comprises at least one of MAPbI₃, MAFACsPbIBr, FAPbI₃, FAPbBr₃, MAPbBr₃, CsPbBr₃, CsPbI₃, (CH₆N)PbI₃, or (C₄H₁₂N)₂PbBr₄.

6. The method of claim 3, wherein the halide perovskite precursors comprise BX₂ and AX.

7. The method of claim 6, wherein BX₂ has a purity between about 95% and about 99.99% on a trace metals basis.

8. The method of claim 1, wherein the impurity comprises a metal.

9. The method of claim 8, wherein the metal comprises at least one of Na, Mg, Al, Si, K, Ca, Cr, Mn, Fe, Co, Ni, Cu, Zn, Ag, Ba, Bi, Rh, Pt, or Pd.

10. The method of claim 1, wherein the first liquid comprises at least one of a polar solvent or an ionic liquid.

11. The method of claim 1, wherein the forming further includes providing an additive to the mixture.

12. The method of claim 1, wherein the preparing is performed with the mixture at a first temperature between about 20° C. and about 180° C.

13. The method of claim 12, wherein the forming is performed with the mixture at a second temperature that is different than the first temperature.

14. The method of claim 1, wherein the forming comprises at least one of evaporating at least a portion of the mixture, applying ultrasound to the mixture, applying a mechanical treatment to the mixture, an acoustical treatment of the mixture, a pressure treatment of the mixture, an electrical treatment of the mixture, or an electromagnetic treatment of the mixture.

15. The method of claim 1, wherein, after the forming, the mixture comprises the halide perovskite crystal and a liquid phase comprising the impurity.

16. The method of claim 15, wherein:
the separating results in the separation of the mixture into the halide perovskite crystal as a solid stream and an effluent stream, and
the effluent stream comprises the liquid phase and the impurity.

17. The method of claim 1, further comprising after the separating, a removing from the halide perovskite crystal any remaining portion of the impurity.

18. The method of claim 1, further comprising:
after the separating, forming a halide perovskite film, wherein the forming utilizes the halide perovskite crystal as a precursor, and
the perovskite film has substantially the same composition of A, B, and X as the halide perovskite crystal precursor.

19. A composition comprising:
a halide perovskite comprising at least one of ABX₃ or A₂BX₄, wherein:
A is a monovalent cation, B is a divalent metal cation, and X is a monovalent halide anion, and
the halide perovskite further comprises N-methylformamidinium.

20. The composition of claim 19, wherein the film further comprises methylammonium at a concentration between 0 wt % and 1 wt %.
